(19) United States
(12) Patent Application Publication
(10) Pub. No.: US 2026/0143889 A1
(43) Pub. Date: May 21, 2026

(54) FULL-COLOR LED DISPLAY AND METHOD OF MANUFACTURING THE SAME

(71) Applicant: Kookmin University Industry Academy Cooperation Foundation, Seoul (KR)

(72) Inventor: Young Rag DO, Seoul (KR)

(21) Appl. No.: 19/393,755

(22) Filed: Nov. 19, 2025

(30) Foreign Application Priority Data
Nov. 19, 2024 (KR) 10-2024-0165628

(51) Int. Cl. H10H 29/851; H10H 20/01; H10H 29/01; H10H 29/03; H10H 29/49

(52) U.S. Cl. CPC H10H 29/8515; H10H 20/0137; H10H 20/017; H10H 29/03; H10H 29/0361; H10H 29/0364; H10H 29/49

(57) ABSTRACT

The present disclosure relates to a full-color light-emitting diode (LED) display. According to the present disclosure, compare to a display employing conventional LED devices, the LED device exhibits high efficiency properties while minimizing surface defects resulting from dry etching of wafers and dead volume resulting from dangling bonds resulting from wet etching, thereby advantageously enabling the achievement of a full-color LED display with higher luminance, luminous efficiency, and resolution.

### CROSS-REFERENCE TO RELATED APPLICATION

The present application claims priority to Korean Patent Application Number 10-2024-0165628, filed on Nov. 19, 2024, the entire disclosure of which is incorporated by reference herein.

### BACKGROUND

### 1. Technical Field

The present disclosure relates to a full-color light-emitting diode (LED) display and a method of manufacturing the same.

### 2. Related Art

Micro light-emitting diodes (μLEDs) are emerging as next-generation display devices. Micro-LED displays offer high performance characteristics and advantages of a theoretically very long lifespan and efficiency. However, when developed to an 8K resolution, nearly one hundred million sub-pixels each require placement of at least one micro-LED, so manufacturing micro-LED displays by pick-and-place techniques encounters process limitations of high cost, high defect rates, and low productivity. In addition, when producing individual micro-LEDs from a wafer, the yield of usable chips decreases, and because current micro-LED sizes are still relatively large, the number of chips that can be fabricated per wafer is small, resulting in very high production costs.

Recently, a method has been proposed to manufacture micro-LED displays by transferring RGB micro-LEDs onto subpixel positions using a laser lift-off (LLO) process.

However, in the LLO process, efficiency degradation occurs due to the laser shock applied during the process, making it unsuitable for use as a transfer process. Moreover, this approach inherits the wafer's non-uniform efficiency into micro-LED devices, leading to uneven luminance in the resulting display.

To address these problems, a method has recently been proposed in which the size of each micro-LED is reduced to 10 μm or less to implement a display, thereby significantly increasing the number of micro-LED chips obtainable from a single wafer while reducing efficiency variation between pixels. However, when fabricating LED chips with sizes of 10 μm or less, not only does the efficiency of each chip decrease significantly but implementing displays via the laser lift-off process with LED chips of 10 μm or less exacerbates chip efficiency loss due to laser shock.

Accordingly, a method has been proposed as an alternative in which a large number of individually separated LED chips of 10 μm or less are assembled into a display by fluidic assembly; nevertheless, even with this alternative, the fundamental problem remains unresolved that external quantum efficiency decreases markedly when micro-LEDs of 10 μm or less are fabricated from a wafer.

In particular, when fabricating micro-LED chips from a wafer by dry-etching, the dead volume due to surface defects increases significantly depending on chip size. For example, when the chip width, length, and thickness are each 92 μm, the dead volume from the surface toward the interior is about 4.69%; when the width, length, and thickness are reduced to 52 μm or 12 μm, the dead volume from the surface toward the interior increases substantially to about 8.3% or 36%, respectively. Consequently, although the number of LED chips obtained from a single wafer increases, the efficiency of each LED chip decreases significantly.

In addition, although wet-etching process may be considered to remove the accumulated dead volume with surface defects as described above, when a substantial dead volume with accumulated surface defects has already formed, wet-etching can remove only part of the surface defects. Furthermore, for GaN wafers fabricated along the c-plane direction, wet-etching increases dangling bonds on the surface, thereby increasing surface strain and non-radiative transitions. As a result, the benefit of efficiency improvement from wet-etching is outweighed by the detrimental effect of increased dangling bonds, and thus the efficiency improvement of the LED chips is relatively limited.

Therefore, there is an urgent need to develop a full-color LED display capable of realizing higher resolution and higher luminance by fabricating LED chips that are small in size and high in efficiency and mounting the same.

### SUMMARY

The present disclosure has been made in view of the above-described problems, and an object of the present disclosure is to provide a full-color LED display and a method of manufacturing the same, which implement a display using individual LED devices while reducing the dead volume caused by surface defects arising from dry-etching in the process of obtaining the individual LED devices from a wafer, so that, despite being realized in small sizes, high-efficiency light-emission characteristics can be exhibited, thereby making it advantageous for the resulting display to achieve higher resolution and higher luminance.

In order to solve the above-described problems, the present disclosure provides a method of manufacturing a full-color LED display, comprising: (1) dispensing, onto a lower electrode line having a plurality of sub-pixel regions formed thereon, a solution containing LED devices, each LED device having a first surface and a second surface opposite to each other in a thickness direction in which a plurality of layers are stacked, and having remaining sidewalls, a thickness of each LED device being 10 μm or less, an area of a cross-section perpendicular to the thickness direction being 100 μm² or less, and an average decay time measured at 300 K being equal to or longer than an average decay time measured at 10 K; (2) self-aligning each LED device introduced into each sub-pixel region on the lower electrode line such that either the first surface or the second surface of each LED device becomes a mounting surface; and (3) forming an upper electrode line on the self-aligned LED devices.

According to an embodiment of the present disclosure, the LED device emits a first color, and after step (3), the method may further include, as step (4), patterning a color conversion layer on the upper electrode line such that at least two of the sub-pixel regions among the plurality of sub-pixel regions emit colors different from the first color.

According to another embodiment of the present disclosure, in step (1), the solution containing the LED devices may include three types of solutions respectively containing blue LED devices, green LED devices, and red LED devices, and each solution may be dispensed onto the lower electrode line such that each sub-pixel region emits a respective chromatic color.

In addition, the LED device may be manufactured dry-etching a wafer downward from an upper surface along a predefined pattern to form a plurality of structures spaced apart from each other between their sidewalls, the dry-etching being performed such that an included angle between a dry-etched sidewall of each structure and a dry-etched bottom surface of the structure continuous with the wafer is 60° to 84°; and wet-etching the structures produced by the dry-etching to remove surface defects on the dry-etched sidewall of each structure, which is defined as a first recovery step.

In addition, the dry-etching may be performed by inductively coupled plasma-reactive ion etching (ICP-RIE) at an etching rate of 200 nm/min or less.

In addition, the inductively coupled plasma-reactive ion etching (ICP-RIE) may be performed under a process condition including a chlorine-based gas comprising 0 to 100 sccm of BCl₃ and 0 to 100 sccm of Cl₂, and a process pressure of 1 to 100 mT.

In addition, the dry-etched LED structure may have an average decay time measured at 300 K that is longer than an average decay time measured at 10 K.

In addition, the dry-etched LED structure may exhibit, in Raman spectral analysis, a ratio of the peak area of a Ga-vacancy-related defect mode located around 687 cm⁻¹ to the peak area of a GaN A₁(LO) mode located around 746.62 cm⁻¹ of 15% or less.

In addition, the first recovery step may be performed such that an included angle between a wet-etched sidewall of each structure and a wet-etched bottom surface of the structure continuous with the wafer is 85° or more.

In addition, each structure may include a first conductive semiconductor layer of a gallium nitride (GaN)-based semiconductor, a light-active layer, and a second conductive semiconductor layer, and a sidewall of the LED structure subjected to the first recovery step may exhibit, in Ga 3d bond analysis by XPS, a change in the ratio of Ga—O bonds—which represent defects among Ga—N and Ga—O bonds—of less than +30% relative to the Ga—O bond ratio of the wafer itself.

In addition, the LED structure after the first recovery step may have an average decay time measured at 300 K that is longer than an average decay time measured at 10 K.

In addition, the LED structure after the first recovery step may have an average decay time measured at 300 K that is longer than that of the LED structure before the first recovery step.

In addition, the LED structure subjected to the first recovery step may exhibit, in Raman spectral analysis, a ratio of the peak area of a Ga-vacancy-related defect mode located around 687 cm⁻¹ to the peak area of a GaN A₁(LO) mode located around 746.62 cm⁻¹ of 8% or less.

In addition, the method may further comprise, after the first recovery step, irradiating the LED structure with UV, which is defined as a second recovery step.

In addition, in the second recovery step, UV having a wavelength of 250 to 400 nm may be irradiated at a power of 1 mW to 100 W for 0.1 to 48 hours.

Meanwhile, in the second recovery step, UV irradiation chemically adsorbs water molecules (H₂O) onto dangling bonds on the etched sidewall, dissociating the water molecules into —OH and —H groups. This process alleviates strain caused by the dangling bonds and enables electrons trapped in shallow and deep traps to be re-trapped into the conduction band, thereby allowing the electrons to participate in light emission and increasing the efficiency of light-emission.

In addition, the LED structure after the second recovery step may have an average decay time measured at 300 K that is longer than an average decay time measured at 10 K.

In addition, the LED structure after the second recovery step may have an average decay time measured at 300 K that is longer than that of the LED structure before the second recovery step.

In addition, the internal quantum efficiency of the LED device may have a value of 70% to 130% relative to the internal quantum efficiency of the wafer itself.

In a first embodiment of the present disclosure, a full-color LED display is provided, which includes a plurality of sub-pixel regions. Each sub-pixel region includes: a lower electrode line; at least one LED device having a first surface and a second surface opposite to each other in a thickness direction in which a plurality of layers are stacked and remaining sidewalls, the LED device being mounted such that either the first surface or the second surface is in contact with the lower electrode line in each sub-pixel region, the LED device having a thickness of 10 μm or less, an area of a cross-section perpendicular to the thickness direction of 100 μm² or less, and an average decay time measured at 300 K that is equal to or longer than an average decay time measured at 10 K, the LED device emitting a first color; an upper electrode line disposed on the LED device; and a color conversion layer provided on the upper electrode line corresponding to each of the plurality of sub-pixel regions, such that each sub-pixel region exhibits one of blue, green, and red colors.

In a second embodiment of the present disclosure, a full-color LED display is provided, which includes a plurality of sub-pixel regions comprising blue, green, and red sub-pixel regions. Each sub-pixel region includes: a lower electrode line; at least one LED device having a first surface and a second surface opposite to each other in a thickness direction in which a plurality of layers are stacked and remaining sidewalls, the LED device being mounted such that either the first surface or the second surface is in contact with the lower electrode line in each sub-pixel region, the LED device having a thickness of 10 μm or less, an area of a cross-section perpendicular to the thickness direction of 100 μm² or less, and an average decay time measured at 300 K that is equal to or longer than an average decay time measured at 10 K, each LED device independently emitting one of blue, green, and red light; and an upper electrode line disposed on the LED device.

According to an embodiment of the first or second embodiment of the present disclosure, an average decay time measured at 300 K may be longer than an average decay time measured at 10 K.

In addition, the average decay time measured at 300 K may be at least 15% longer than the average decay time measured at 10 K.

In addition, in emission measured at 300 K, delayed luminescence arising from shallow and deep traps may contribute more than band-gap luminescence.

In addition, in emission measured at 300 K, delayed luminescence arising from shallow and deep traps may contribute at least twice as much as band-gap luminescence.

In addition, the LED device may include a first conductive semiconductor layer, a light-active layer, and a second conductive semiconductor layer of a gallium nitride (GaN)-based semiconductor. In Raman spectral analysis, the LED device may exhibit a ratio of the peak area of a Ga-vacancy-related defect mode located around 687 cm 1 to the peak area of a GaN A₁(LO) mode located around 746.62 cm⁻¹ of 8% or less, and in another example, 6% or less.

In addition, a sidewall of the LED device may exhibit, in Ga 3d bond analysis by X-ray photoelectron spectroscopy (XPS), a change in the ratio of Ga—O bonds—which represent defects among Ga—N and Ga—O bonds—of less than +30% relative to the Ga—O bond ratio of the wafer itself.

Hereinafter, terms used in the present disclosure are defined.

In the description of embodiments according to the present disclosure, when each layer, region, line, or substrate is described as being “on,” “upper,” “over,” “under,” “lower,” or “below” another element, the terms “on,” “upper,” “over,” “under,” “lower,” and “below” include both meanings of “directly” and “indirectly.”

Meanwhile, it is stated that the present disclosure was made with the support of the following national research and development project.
[Assignment Unique Number] 1711199993
[Assignment Number] 00281346 (RS-2023-00281346)
[Name of the Ministry] Korea Ministry of Science and ICT
[Name of the Assignment Managing (Professional) Organization] National Research Foundation of Korea
[Research Project Title] Nano and Materials Technology Development Project (Strategic)
[Project Name] 300 ppi High-Resolution Inorganic Light Emitting Diode with Intrinsic Stretch of 30% or More Development of Display Materials and Process Technology
[Project Implementing Organization] Hongik University Industry-Academic Cooperation Foundation
[Research Period] Aug. 1, 2023-Dec. 31, 2027
[Assignment Unique Number] 1415184818
[Assignment Number] 20016290
[Name of the Ministry] Ministry of Trade, Industry and Energy
[Name of the Assignment Managing (Professional) Organization] Korea Institute of Industrial Technology Evaluation and Planning
[Research Project Title] Electronic Components Industry Technology Development (R&D)
[Project Name] Development of Sub-micron Blue Light-Emitting Diode Technology for Modular Displays
[Project Implementing Organization] Korea Electronics Technology Institute
[Research Period] Apr. 1, 2021-Dec. 31, 2024

In contrast to a display employing conventional LED devices, the full-color LED display according to the present disclosure minimizes dead volume caused by surface defects arising from wafer dry-etching and by dangling bonds generated during wet-etching. Moreover, because wet-etching, which serves as a recovery process to remove surface defects during LED device fabrication, can instead generate dangling bonds on the side surface of the device, an additional recovery process is performed by irradiating UV light to adsorb water molecules onto the dangling bonds, thereby minimizing surface strain of the LED devices. As a result, the display is equipped with LED devices that exhibit further improved, high-efficiency properties, which makes it advantageous to achieve higher luminance, optical efficiency, and resolution in a full-color LED display.

### BRIEF DESCRIPTION OF THE DRAWINGS

FIGS. 1 and 2 are views showing a full-color LED display according to a first embodiment of the present disclosure, wherein FIG. 1 is a plan view of the full-color LED display, and FIG. 2 is a cross-sectional schematic view taken along line A-A′ of FIG. 1.

FIGS. 3 and 4 are views showing an LED device included in an embodiment of the present disclosure,

wherein FIG. 3 is a perspective view of the LED device, and FIG. 4 is a cross-sectional schematic view taken along line X-X′ of FIG. 3.

FIGS. 5 and 6 are cross-sectional schematic views of LED devices included in an embodiment of the present disclosure.

FIG. 7 is a cross-sectional schematic view of a full-color LED display according to another embodiment, taken along line A-A′ of FIG. 2.

FIG. 8 is a perspective view and a partially enlarged view of an LED device included in an embodiment of the present disclosure shown in FIG. 7.

FIGS. 9 and 10 are views showing a full-color LED display according to a second embodiment of the present disclosure, wherein FIG. 9 is a plan view of the full-color LED display, and FIG. 10 is a cross-sectional schematic view taken along line B-B′ of FIG. 9.

FIG. 11 is a cross-sectional schematic view of a full-color LED display according to another embodiment, taken along line B-B′ of FIG. 10.

FIG. 12 is a process schematic diagram showing a method of manufacturing an LED device included in an embodiment of the present disclosure.

FIG. 13A shows a pair of schematic views and SEM images of cross-sections for each step according to a method of manufacturing an LED device included in an example of the present disclosure, wherein the left schematic view and SEM image correspond to step (I), and the right schematic view and SEM image correspond to step (II).

FIG. 13B shows a pair of schematic views and SEM images of cross-sections for each step according to method of manufacturing an LED device included in a comparative example, wherein the left schematic view and SEM image correspond to step (I), and the right schematic view and SEM image correspond to step (II).

FIG. 14 shows a TEM image (left), a high-resolution TEM image (center), and a diffraction pattern image (right) of an LED device manufactured by performing only step (I) according to a method of manufacturing an LED device included in an example of the present disclosure.

FIG. 15 shows a TEM image (left), a high-resolution TEM image (center), and a diffraction pattern image (right) of an LED device manufactured by performing only step (I) according to a method of manufacturing an LED device according to a comparative example of the present disclosure.

FIG. 16 is a Raman spectrum of a sidewall, which is etched surface of an LED device manufactured according to an example of the present disclosure and a comparative example.

FIG. 17 is an XPS spectrum of a sidewall, which is etched surface of an LED device manufactured according to an example of the present disclosure and a comparative example.

FIG. 18 is a bar graph obtained by separating Ga—O, Ga—Ga, and Ga—N spectra from a Ga 3d binding peak spectrum of FIG. 17 and quantifying the relative amounts of each binding.

FIGS. 19 and 20 are photoluminescence (PL) graphs measured at 300 K and 10 K, respectively, for LED devices manufactured according to an example of the present disclosure and a comparative example.

FIG. 21 is a graph of internal quantum efficiency by temperature calculated using the results of FIGS. 19 and 20. Here, in the table within the figure, “Pristine” refers to the wafer itself, “HDDE” refers to Comparative Preparation Example 1, “LDDE” refers to Preparation Example 1, “HDDE/SWE” refers to Comparative Example 1, and “LDDE/SWE” refers to Example 1.

FIG. 22 is a graph of average decay time for LED devices manufactured according to an example of the present disclosure and a comparative example. In the table within the figure, “Pristine” refers to the wafer itself, “HDDE” to Comparative Preparation Example 1, “LDDE” to Preparation Example 1, “HDDE/SWE” to Comparative Example 1, and LDDE/SWE to Example 1.

FIG. 23 is a schematic diagram showing the light emission mechanisms of a recoverable low-damage dry-etching (right) included in a method of manufacturing an LED device according to an example of the present disclosure, and a limited high-damage dry-etching (left) that falls outside the scope of the present disclosure.

FIGS. 24 and 25 are PL emission graphs measured by varying the UV irradiation time, which is the second recovery step, during the manufacture of an LED device according to an example of the present disclosure and a comparative example.

FIG. 26 is a graph of internal quantum efficiency calculated using the results of FIGS. 19 and 20 (PL changes by temperature) of an LED device manufactured according to an example of the present disclosure and a comparative example in which UV irradiation is performed as a second recovery step.

FIGS. 27 and 28 are graphs of decay time for LED devices manufactured according to an example of the present disclosure and a comparative example in which UV irradiation is performed as a second recovery step, respectively.

FIG. 29 is a schematic diagram showing a light emission mechanism explaining the delayed photoluminescence (PL) phenomenon of an LED device manufactured by performing UV irradiation as a second recovery step in a method of manufacturing an LED according to an example of the present disclosure.

FIGS. 30 and 31 are graphs of luminance and external quantum efficiency measured by varying current densities through a full-color LED display, each employing an LED device manufactured according to an example of the present disclosure and a comparative example, in which UV irradiation is performed as a second recovery step.

### DETAILED DESCRIPTION

Hereinafter, embodiments of the present disclosure will be described in detail with reference to the accompanying drawings so that those skilled in the art to which the present disclosure pertains can easily carry out the invention. It should be understood that the present disclosure may be embodied in various different forms and is not limited to the embodiments described herein.

First, a full-color LED display according to a first embodiment of the present disclosure, which is implemented with LED devices emitting substantially the same chromatic color (first color), will be described.

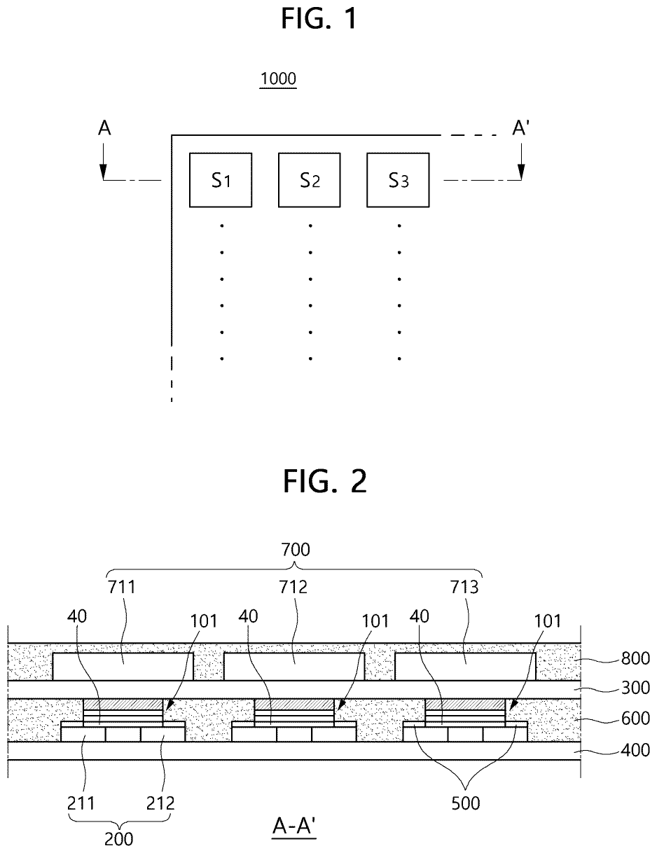

Referring to FIGS. 1 to 2 and 7, a full-color LED display 1000, 1000′ according to a first embodiment of the present disclosure includes a plurality of sub-pixel regions S₁, S₂, S₃, wherein the sub-pixel regions S₁, S₂, S₃ comprise: a lower electrode line 200, 200′; at least one LED device 101, 104 that emits a first color and is mounted on the lower electrode line 200, 200′ such that one of a first surface and a second surface, which are opposite to each other in a thickness direction, contacts the lower electrode line for each sub-pixel region; an upper electrode line 300 disposed on the LED device 101, 104; and a color conversion layer 700 provided on the upper electrode line 300 corresponding to the sub-pixel regions S₁, S₂, S₃ such that each of the plurality of sub-pixel regions exhibits one of blue, green, and red.

The plurality of sub-pixel regions S₁, S₂, S₃ may constitute one pixel. For example, each sub-pixel region S₁, S₂, S₃ may be defined by a data line and a gate line disposed on a substrate. In a specific example, the sub-pixel region may be defined as a point at which a data line and a gate line intersect, or as a region including the point.

In addition, the sub-pixel regions S₁, S₂, S₃ may have a unit area of, for example, 1 μm² to 100 cm², and more preferably 10 μm² to 100 mm², without being limited thereto. Meanwhile, the unit area of each sub-pixel region may be different from one another. Further, a separate surface treatment may be performed on the surfaces of the sub-pixel regions, or grooves may be formed therein.

In addition, a thin-film transistor (TFT) may be disposed in each of the sub-pixel regions S₁, S₂, S₃. Specifically, the transistor may be disposed at a point where a data line and a gate line intersect. For example, the data line may be connected to a source electrode of the transistor, and the gate line may be connected to a gate electrode of the transistor. Further, the transistor may have either an inverted stagger structure (bottom-gate type) or a stagger structure (top-gate type) based on the position of the gate electrode. In addition, according to the arrangement of the gate electrode and an active layer, the transistor may have one of four structures, that is, bottom gate-top contact, bottom gate-bottom contact, top gate-top contact, or top gate-bottom contact.

Meanwhile, although FIG. 1 does not illustrate the above-described data lines, gate lines, and transistors, a layout design commonly used in conventional displays may be adopted for the arrangement of these unillustrated components, and thus a detailed description thereof is omitted herein.

In addition, at least one LED device 101, 104 is disposed in each of the sub-pixel regions S₁, S₂, S₃, and the arrangement includes a lower electrode line 200, 200′ and an upper electrode line 300 that are disposed opposite to each other so as to respectively contact upper and lower portions of the LED device 101, 104. Here, the lower electrode line 200, 200′ may be provided on a substrate on which a transistor disposed in each of the sub-pixel regions S₁, S₂, S₃ is provided.

For example, the lower electrode line 200, 200′ may be formed on a base substrate 400. The base substrate 400 may function as a support for supporting a display panel. The base substrate 400 may be a known substrate used for light sources of displays or the like, and the present disclosure is not particularly limited with respect to the material, area, or thickness of the base substrate. In consideration of light transmittance, the base substrate may be transparent, and, specifically, glass or plastic may be selected, but the present disclosure is not limited thereto. In addition, the base substrate may be made of a flexible material. Furthermore, the size and thickness of the base substrate may be appropriately varied in consideration of the size and number of the LED devices to be provided and the specific design of the lower electrode line 200, 200′, and therefore the present disclosure is not particularly limited thereto.

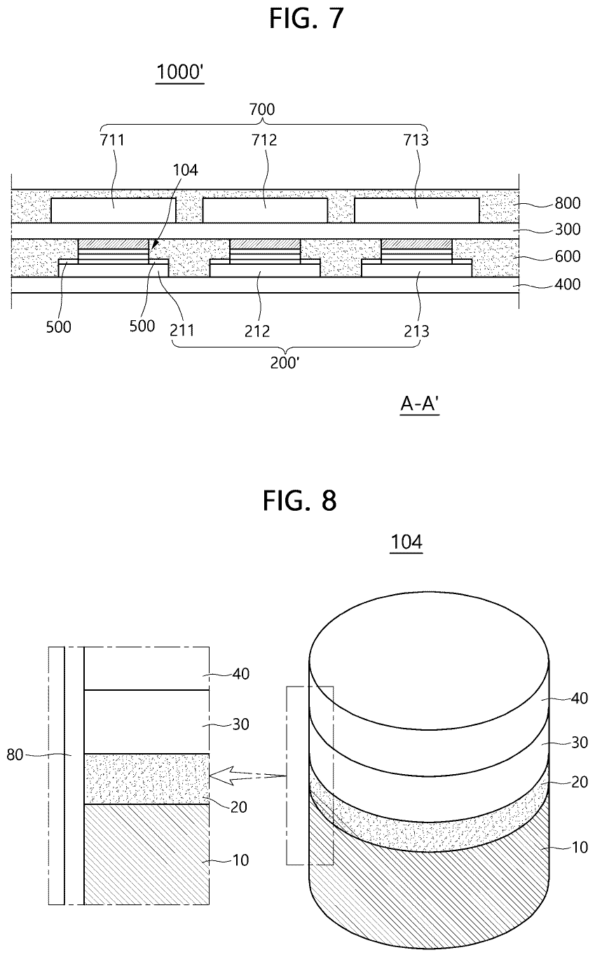

It is to be noted that, unlike what is shown in FIGS. 2 and 7, the lower electrode line 200, 200′ may be formed on a passivation layer having a planar surface rather than on the base substrate 400, and known circuit components employed in displays, such as thin-film transistors, may be disposed below the passivation layer.

In addition, the lower electrode line 200, 200′ and the upper electrode line 300 are arranged in a vertical direction. Such a vertical arrangement simplifies electrode design and improves implement ability compared with horizontal electrode lines in which two electrodes (e.g., +/−) implemented with ultra-small thickness and width are arranged to be spaced apart from each other at micro- or nano-scale intervals with their lateral sides facing each other. Moreover, because the vertical arrangement also facilitates TFT array layout, not only active-matrix driving but also passive-matrix driving using an x-y matrix becomes feasible, thereby allowing conventional display electrode designs and control techniques to be adopted as they are.

Further, the lower electrode line 200, 200′ and the upper electrode line 300 may each include at least one lower electrode 201, 202, 211, 212, 213 and one or more upper electrodes. The specific number, spacing, and arrangement thereof may be appropriately modified in consideration of the area and luminance of the display to be implemented, and therefore the present disclosure is not particularly limited thereto.

Further, when the upper electrode line 300 is designed to be in electrical contact with a surface opposite to the mounting surface of the LED device 101, 104 mounted on the lower electrode line 200, 200′, there is no particular limitation on the number or arrangement thereof. For example, when the lower electrode lines 200, 200′ are arranged parallel to each other in one direction, the upper electrode line 300 may be arranged perpendicular to that direction.

Further, the lower electrode line 200, 200′ and the upper electrode line 300 may have materials, shapes, widths, and thicknesses corresponding to those of electrodes used in displays employing conventional LED devices. Since these electrodes can be manufactured using known methods, the present disclosure does not particularly limit them. For example, the lower electrode line 200, 200′ and the upper electrode line 300 may each independently be aluminum, chromium, gold, silver, copper, graphene, indium tin oxide (ITO), or an alloy thereof, and may have a width of 2 to 50 μm and a thickness of 0.1 to 100 μm; however, these parameters may be appropriately varied in consideration of factors such as the area of the LED display and the area of the sub-pixel regions.

Next, an LED device 101, 104 disposed between the above-described lower electrode line 200, 200′ and the upper electrode line 300 will be described.

The LED device 101, 104 may be arranged such that at least one is included for each of the plurality of sub-pixel regions S₁, S₂, S₃ on the lower electrode line 200. In addition, when two or more LED devices 101, 104 are disposed for each sub-pixel region S₁, S₂, S₃, even if a defective device is included among the disposed LED devices, light emission can be achieved through another LED device, and all sub-pixels can emit a predetermined first color, thereby minimizing or preventing the occurrence of defective pixels in the display.

In addition, the LED device 101, 104 provided for each sub-pixel region S₁, S₂, S₃ emits a predetermined first color as substantially the same chromatic color. Here, “substantially the same chromatic color” does not mean that the wavelengths of the emitted light are completely identical, but rather that the emitted light falls within a wavelength range generally referred to as the same chromatic color. For example, when the chromatic color is blue, an LED device that emits light within a wavelength range of 420 to 470 nm can be regarded as emitting substantially the same chromatic color. The chromatic color of the light emitted by the LED device 101, 104 included in the full-color LED display 1000 according to the first embodiment of the present disclosure may be, for example, blue, white, or ultraviolet (UV).

Additionally, as shown in FIG. 2, a single LED device 101 may be mounted such that a first surface or a second surface is in contact with two adjacent lower electrodes 201, 202. Alternatively, as shown in FIG. 7, a single LED device 104 may be mounted such that a first surface or a second surface is in contact with one lower electrode 211, 212, 213.

In addition, the LED device 101, 104 exhibits a characteristic such that the average decay time measured at 300 K is equal to or, preferably, longer than the average decay time measured at 10 K. Such temperature-dependent afterglow behavior is exhibited as defects formed on the surface during the dry-etching process are substantially removed while remaining defects are passivated, thereby facilitating trapping and detrapping at room temperature. As a result, the internal quantum efficiency of the LED device 101, 104 approaches that of the source wafer from which it originates, enabling the LED device 101, 104 to exhibit high-efficiency properties.

Additionally, LED devices 101, 104 having such high efficiency are fabricated by a top-down approach, which are obtained by etching a wafer so as to separate individual devices, and may be manufactured by the following method so that defects generated during and after etching are removed.

Specifically, the LED devices 101, 104 may be manufactured by a process including: (I) dry-etching a wafer downward from an upper surface along a predefined pattern to form a plurality of structures spaced apart from each other between their sidewalls, the dry-etching being performed such that an included angle between an etched sidewall of each structure and an etched bottom surface of the structure continuous with the wafer is 84° or less; (II) as a first recovery step, wet-etching the sidewall of each structure formed by the dry-etching to remove surface defects; and (III) separating the plurality of structures from the wafer.

As a first step (I), a process of dry-etching a wafer downward in a thickness direction according to a predefined pattern to form a plurality of structures will be described.

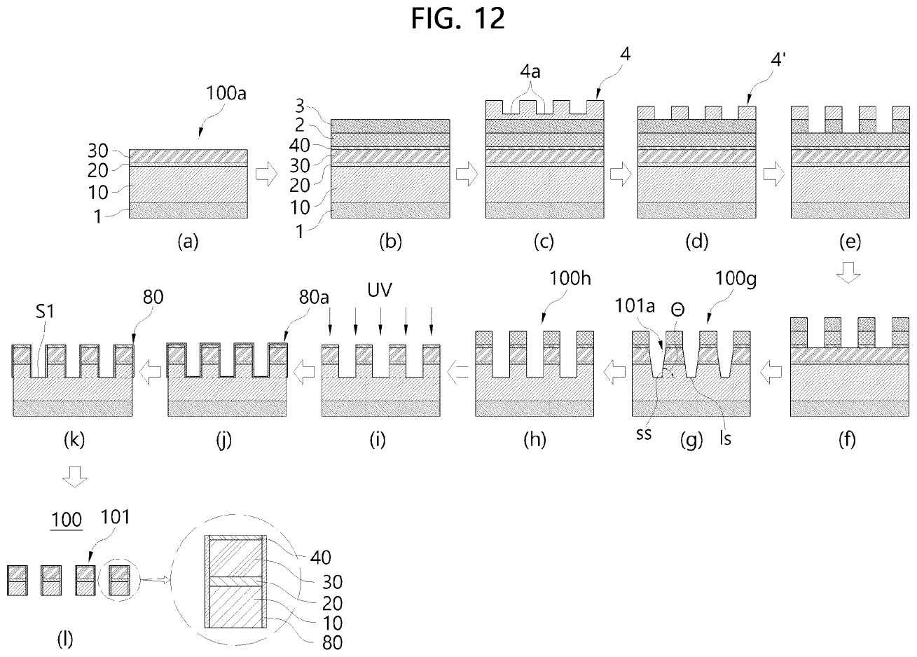

Referring to FIG. 12, in step (I), the prepared wafer 100a may be any commercially available wafer without particular limitation. For example, the wafer 100a may include, as a minimum structure, a substrate 1, a first conductive semiconductor layer 10, a light-active layer 20, and a second conductive semiconductor layer 30. In this case, the first conductive semiconductor layer 10 may be an n-type conductive semiconductor layer, and the second conductive semiconductor layer 30 may be a p-type conductive semiconductor layer. The n-type and p-type conductive semiconductor layers may be formed of any known conductive semiconductor layers used in light-emitting diodes without particular limitation. For example, the n-type and p-type conductive semiconductor layers may include group III-V compound semiconductors, generally referred to as group III-nitride materials, and more particularly, binary, ternary, or quaternary alloys of gallium, aluminum, indium, and nitrogen.

Specifically, the first conductive semiconductor layer 10, which is an n-type conductive semiconductor layer, may be selected from one or more semiconductor materials having the composition formula InxAlyGa1-x-yN (0≤x≤1, 0≤y≤1, 0≤x+y≤1), such as InAlGaN, GaN, AlGaN, InGaN, AlN, or InN. As a specific example, it may include gallium nitride (GaN), and the first conductive dopant (e.g., Si, Ge, Sn) may be doped. Also, as an example, the thickness of the first conductive semiconductor layer 10 in the wafer may be 100 nm to 20 μm.

In addition, the second conductive semiconductor layer 30, which is a p-type conductive semiconductor layer, may be selected from one or more semiconductor materials having the composition formula InxAlyGa1-x-yN (0≤x≤1, 0≤y≤1, 0≤x+y≤1), such as InAlGaN, GaN, AlGaN, InGaN, AlN, InN, and the like; as a specific example, it may include gallium nitride (GaN), and the second conductive dopant (e.g., Mg) may be doped. According to a preferred embodiment of the present disclosure, the thickness of the second conductive semiconductor layer 30 may be 50 to 150 nm, but is not limited thereto.

In addition, a light-active layer 20 disposed between the first conductive semiconductor layer 10 and the second conductive semiconductor layer 30 may be formed as a single or multiple quantum well structure. The light-active layer 20 may be any light-active layer included in a conventional LED device used for illumination or display applications without particular limitation. One or more cladding layers (not shown) doped with a conductive dopant may be formed above and/or below the light-active layer 20, and the cladding layers doped with the conductive dopant may be implemented as AlGaN layers or InAlGaN layers. In addition, materials such as AlGaN or AlInGaN may also be used for the light-active layer 20. When an electric field is applied to the device, electrons and holes respectively injected from the conductive semiconductor layers located above and below the light-active layer 20 recombine within the light-active layer, thereby causing light emission. According to a preferred embodiment of the present disclosure, the light-active layer 20 may have a thickness ranging from 50 nm to 200 nm, but is not limited thereto.

Meanwhile, each layer within the wafer 100a may have a c-plane crystal structure. In addition, the wafer 100a may have undergone a cleaning process, and since the cleaning process may appropriately employ a conventional cleaning solution and procedure used for wafers, the present disclosure is not particularly limited thereto. The cleaning solution may include, for example, isopropyl alcohol, acetone, or hydrochloric acid, but is not limited thereto.

Meanwhile, an electrode layer 40 may be additionally formed on the second conductive semiconductor layer 30 of the above-described wafer 100a ((b) of FIG. 12). The electrode layer 40 may be used without limitation in the case of an electrode layer included in a conventional LED device used for lighting, display, or the like. The electrode layer 40 may be a single layer formed of one selected from Cr, Ti, Al, Au, Ni, ITO, and oxides or alloys thereof; or a single layer in which two or more types are mixed; or a composite layer in which two or more materials each form a layer.

The electrode layer 40 may be formed by a conventional method of forming an electrode layer on a semiconductor layer, and may be formed, for example, by deposition through sputtering. In addition, the electrode layer 40 may have a thickness of 10 to 500 nm, but is not limited thereto. Furthermore, the electrode layer 40 may undergo a rapid thermal annealing process after deposition. The rapid thermal annealing process may be performed, for example, at 600° C. for 10 minutes, but may be appropriately adjusted considering the thickness, material, and the like of the electrode layer; therefore, the present disclosure is not particularly limited thereto.

Next, the prepared wafer 100a ((a) of FIG. 12, 100a) may have its upper surface patterned with a predefined pattern so that a plane perpendicular to the thickness direction, which is the direction in which layers are stacked in the finally implemented individual LED devices 101, has a desired shape and a size of 100 μm² or less ((b) to (f) of FIG. 12). Specifically, assuming a case where an electrode layer 40 is additionally formed on the wafer 100a, a mask pattern layer may be formed on the upper surface of the electrode layer 40. The mask pattern layer may be formed by a known method and material used for wafer etching, and the pattern of the pattern layer may be formed by appropriately applying a conventional photolithography method or a nanoimprinting method.

As an example, the mask pattern layer may be a laminate of a first mask layer 2, a second mask layer 3, and a resin pattern layer 4′ formed by forming a predetermined pattern on the electrode layer 40, as shown in (d) of FIG. 12. Briefly describing a method of forming the mask pattern layer, as an example, the first mask layer 2 and the second mask layer 3 are formed on the electrode layer 40 by deposition ((b) of FIG. 12), then a patterned resin layer 4, which is the origin of the resin pattern layer 4′, is formed on the second mask layer 3 ((c) of FIG. 12). Subsequently, the residual resin portion 4a of the resin layer 4 is removed by a conventional method such as reactive ion etching (RIE) to realize the resin pattern layer 4′ ((d) of FIG. 12). Then, the second mask layer 3, the first mask layer 2, and the electrode layer 40 are sequentially etched ((e) and (f) of FIG. 12) along the pattern. At this time, the first mask layer 2 may be formed of silicon dioxide as an example, and the second mask layer 3 may be a metal layer such as aluminum or nickel. The etching of these layers may be performed by reactive ion etching (RIE) and inductively coupled plasma (ICP), respectively. Meanwhile, during the etching of the first mask layer 2, the resin pattern layer 4′ may also be removed ((f) of FIG. 12).

Meanwhile, the patterned resin layer 4, which is the origin of the resin pattern layer 4′, may be formed by known methods such as nanoimprinting, photolithography using a photosensitive material, laser interference lithography, or electron beam lithography, and the present disclosure is not particularly limited thereto.

Thereafter, as shown in (f) of FIG. 12, a wafer 100g having a plurality of structures 101a spaced apart from each other between their sidewalls may be obtained by performing dry-etching from an upper portion of the wafer 100a downward in the thickness direction along a predefined pattern on the second conductive semiconductor layer 30, as shown in (g) of FIG. 12. At this time, the dry-etching may be performed to at least a portion of the thickness of the first conductive semiconductor layer 10 in the wafer 100a, which can be appropriately controlled in consideration of the thickness of the first conductive semiconductor layer 10 in the LED device to be manufactured and the thickness of the first conductive semiconductor layer 10 within the wafer.

The dry-etching may be performed by inductively coupled plasma-reactive ion etching (ICP-RIE), wherein preferably, chemical etching predominates over physical etching during the ICP-RIE process. Furthermore, preferably, the dry-etching performed by ICP-RIE is such that chemical etching is more dominant than physical etching, such that an included angle (θ) formed between a sidewall (ss) of a structure 101a, which is an etched surface, and a bottom surface (Is) of the structure continuous with the wafer is 84° or less, and preferably 60° to 84°. When the dry-etching is performed to obtain such an included angle, the etched sidewall of the structure exhibits a reduced amount of surface defects, and the generated surface defects have characteristics that can be recovered in the subsequent first recovery step (II). As a result, the recoverable range of the surface defects can be increased, and both the internal quantum efficiency and external quantum efficiency of the obtained LED device 101 can be significantly improved.

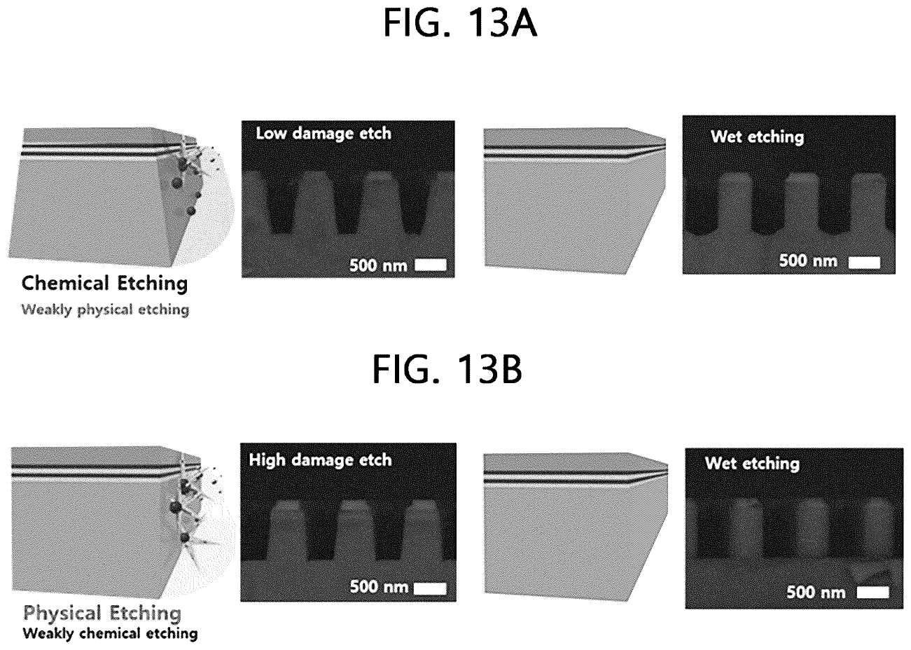

Referring to FIGS. 13A and 13B, the included angle formed between an etched surface and a main surface of the wafer varies depending on whether the dry-etching performed through inductively coupled plasma-reactive ion etching (ICP-RIE) is dominated by physical etching or by chemical etching. Specifically, as shown in FIG. 13B, when the dry-etching performed through ICP-RIE is dominated by physical etching rather than chemical etching, the etched surface may be formed at an angle of 85° or greater, approaching approximately 90°, with respect to the main surface of the wafer. In contrast, as shown in FIG. 13A, when the dry-etching performed through ICP-RIE is dominated by chemical etching rather than physical etching, the etched surface may be formed in a tapered shape, such that it is not perpendicular but inclined with respect to the bottom surface of the structure (or the main surface of the wafer). Accordingly, in the manufacturing method of the present disclosure, the dry-etching is performed through inductively coupled plasma-reactive ion etching (ICP-RIE) under conditions in which chemical etching is more dominant than physical etching. As a result, the etched profile after the dry-etching has a tapered shape, and the degree of dominance of the chemical etching over the physical etching may be controlled such that an included angle (θ) formed between an etched sidewall (ss) of a structure 101a, and an etched bottom surface (Is) of the structure 101a continuous with the wafer is 84° or less. If the dry-etching performed through ICP-RIE is dominated by physical etching (see FIG. 13B), or even when chemical etching is dominant but the included angle (θ) formed between the etched sidewall (ss) of the structure 101a and the etched bottom surface (Is) of the structure continuous with the wafer exceeds 84°, a high-damage dry-etching having limited recoverability (in which recovery is impossible or only partial recovery can be achieved) may occur, resulting in a large dead volume. In such a case, even if the subsequent first recovery step (II) removes an amorphous surface structure generated on the dry-etched sidewall (ss) of the structure 101a, a large amount and various types of surface defects may still remain, and thus the improvement in light-emission efficiency may be limited.

Hereinafter, in the description of the LED device manufacturing method, a dry-etching mode in which physical etching is more dominant than chemical etching-specifically, where the etched surface is formed at an angle of 85° or greater, or approximately perpendicular (about) 90° with respect to the main surface of the wafer-will be referred to as a limited high-damage dry-etching or simply a high-damage dry-etching. In addition, a dry-etching mode in which chemical etching is more dominant than physical etching and in which the included angle (θ) formed between the etched sidewall (ss) of the structure 101a and the etched bottom surface (Is) of the structure continuous with the wafer is 84° or less, will be referred to as a recoverable low-damage dry-etching or simply a low-damage dry-etching.

The surface defects generated by the above-described dry-etching in step (I) may include defects arising from amorphous regions formed near the surface of the etched plane and from group-III element deficiencies (for example, Ga deficiency).

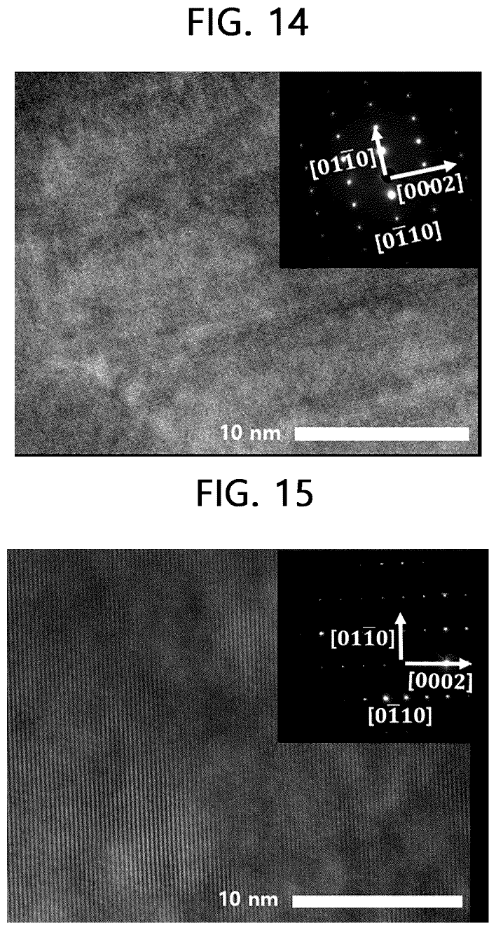

Referring to FIGS. 14 and 15, diffraction patterns (overlapped images on the right side of each photograph) show that the overall crystal structure is nearly unchanged and well preserved in both the LED structure produced by the limited high-damage dry-etching (FIG. 15) and that implemented by the recoverable low-damage dry-etching (FIG. 14). However, when comparing the high-resolution TEM images (background images), the LED structure subjected to the limited high-damage dry-etching appears to have larger dark-spot regions corresponding to surface defects and internal defects, that is, dead volumes, than the LED structure subjected to the recoverable low-damage dry-etching. Therefore, it can be inferred that the high-damage dry-etching generates a greater number of surface defects compared with the low-damage dry-etching.

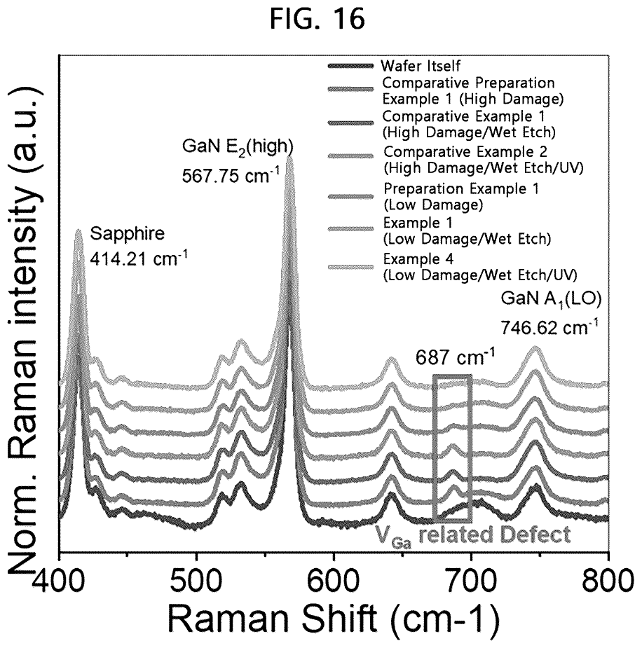

Referring to FIG. 16, in the case of the limited high-damage dry-etching, a defect peak attributed to Ga-vacancy defects appears near a wavenumber of 687 cm⁻¹, and even in the case of the recoverable low-damage dry-etching, a small Ga-vacancy-related-related defect can still be observed. From these results, it can be understood that the defects generated by the dry-etching include not only the increased structural defects confirmed from FIGS. 14 and 15, but also group-III element-vacancy defects, such as Ga-vacancy defects. However, the amount of such group-III element-vacancy defects, specifically Ga-vacancy defects, differs greatly between the two etching modes: in the limited high-damage dry-etching corresponding to a conventional vertical dry-etching process, a large quantity of Ga-vacancy defects is produced, whereas in the recoverable low-damage dry-etching, only a very small amount of Ga-vacancy defects is observed. Accordingly, a clear difference in the total amount of defects after the dry-etching can be identified between the two etching modes.

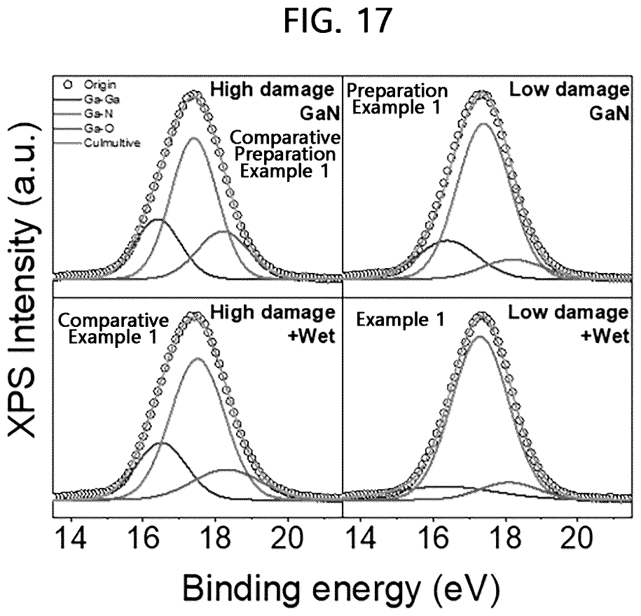

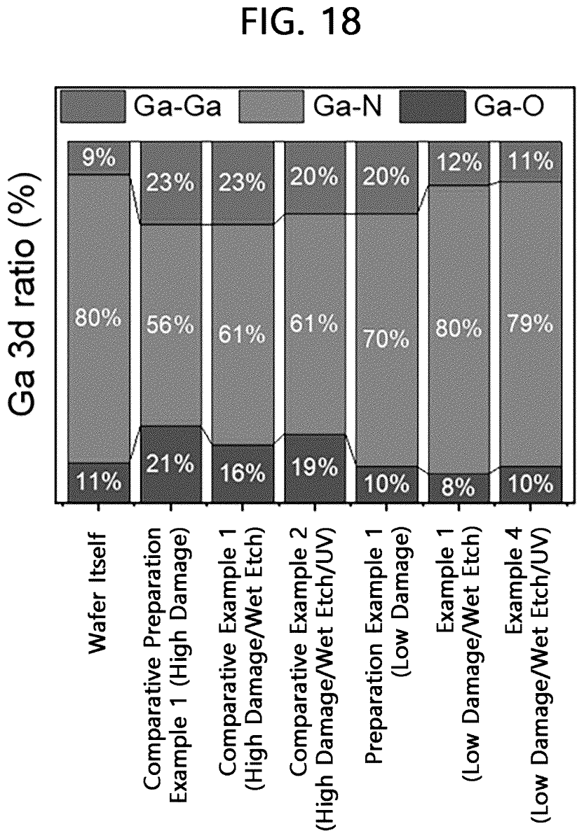

Referring to FIGS. 17 and 18, when the Ga 3d peaks in the XPS spectra are measured and deconvoluted by bonding type, it can be confirmed that both the limited high-damage dry-etching and the recoverable low-damage dry-etching exhibit not only Ga—N bonds but also Ga—Ga and Ga—O bonds corresponding to defect states.

However, when the relative amounts of each bonding type are quantified by deconvoluting the Ga 3d peaks in the XPS spectra, the structure produced by the limited high-damage dry-etching shows that the ratio of Ga—O bonds increases by approximately 90.1%, from 11% in the wafer itself after dry-etching to 21%, and the ratio of Ga—Ga bonds increases by approximately 155.5%, from 9% in the wafer itself to 23%. In contrast, the structure fabricated by the recoverable low-damage dry-etching shows that the Ga—O bond ratio decreases by about 9.1%, from 11% in the wafer itself after dry-etching to 10%, indicating that the recoverable low-damage dry-etching reduces Ga—O bonds compared with the limited high-damage dry-etching and even decreases the inherent Ga—O bonds present in the wafer. These results indicate that, although both etching methods can generate Ga—O and/or Ga—Ga bonds that constitute major surface defects after dry-etching, there is a significant difference in the total amount of generated defects between the two methods, and the recoverable low-damage dry-etching produces a smaller amount of defects—or virtually none—compared with the limited high-damage dry-etching.

In addition, it is noteworthy that even for the same type of defect, the degree of defect recovery during the subsequent recovery process varies significantly depending on the conditions under which the dry-etching is performed. Referring to FIG. 16, in the case of the structure subjected to the limited high-damage dry-etching in which a large amount of Ga-vacancy defects are generated, the subsequent wet-etching process, that is, the first recovery step, results in only a slight reduction in the Ga-vacancy-related peak, which remains almost unchanged. In contrast, in the case of the structure subjected to the recoverable low-damage dry-etching, the Ga-vacancy defects are hardly observed after the subsequent wet-etching process corresponding to the first recovery step.

Meanwhile, when the Raman spectrum is analyzed for the sidewall of the LED structure subjected to step (1), which is the recoverable low-damage dry-etching, the peak area ratio of the Ga-vacancy-related defect mode located at 687 cm⁻¹ to the GaN A₁(LO) mode located at 746.62 cm 1 may be 15% or less. In addition, when the Raman spectrum is analyzed for the sidewall of the LED structure after performing step (2), which is the first recovery step involving wet-etching following the recoverable low-damage dry-etching, the peak area ratio of the Ga-vacancy-related defect mode located at 687 cm⁻¹ to the GaN A₁(LO) mode located at 746.62 cm 1 may be 8% or less.

Specifically, referring to FIG. 16, in the Raman spectrum, the peak area ratio of the Ga-vacancy-related defect mode located at 687 cm⁻¹ to the GaN A₁(LO) mode located at 746.62 cm⁻¹ is 23.5% after the limited high-damage dry-etching, whereas the peak area ratio is only 10.6% after the recoverable low-damage dry-etching, indicating that the generation of Ga-vacancy defects is significantly reduced.

Meanwhile, the fact that the structure produced by the limited high-damage dry-etching exhibits little defect recovery even after undergoing the first recovery step involving wet-etching can also be confirmed through quantum efficiency calculations.

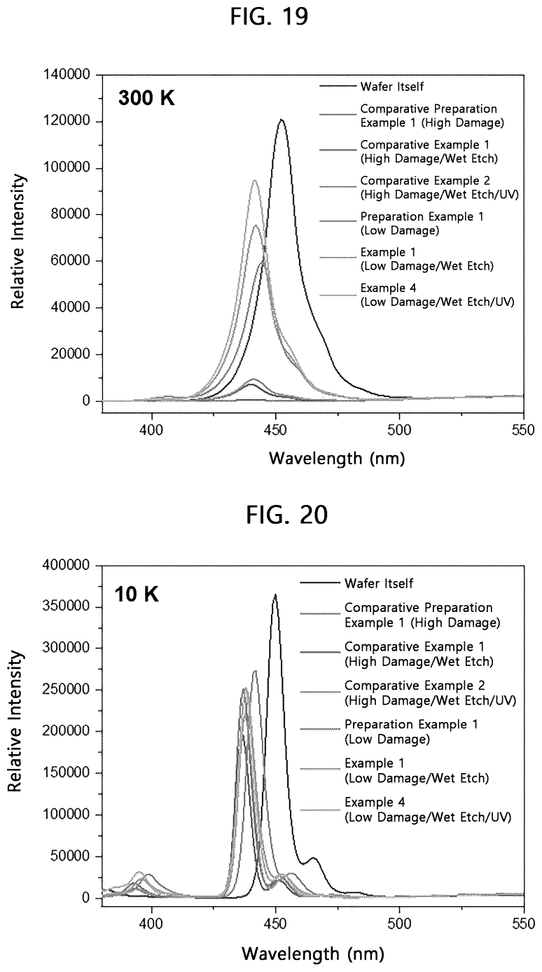

Specifically, referring to FIG. 19, at a low temperature of 10 K, the photoluminescence (PL) intensities of all samples are almost identical regardless of the etching method. This result can be explained by the fact that, at low temperatures, electrons excited at surface defects are not captured, so yellow emission caused by defect states and nonradiative recombination are quenched and nearly disappear.

Consequently, excitons between the conduction band and the valence band predominantly participate in radiative recombination, thereby increasing blue emission and making the PL intensities of most samples nearly the same.

However, as shown in FIG. 20, when the PL is measured at room temperature (300 K), a large number of surface defects are generated in the sample subjected to the limited high-damage dry-etching. Even though the amorphous surface structure is removed through wet-etching, a considerable amount of surface defects still remains, so that the intensity of blue emission is partially recovered but does not increase to a desired level.

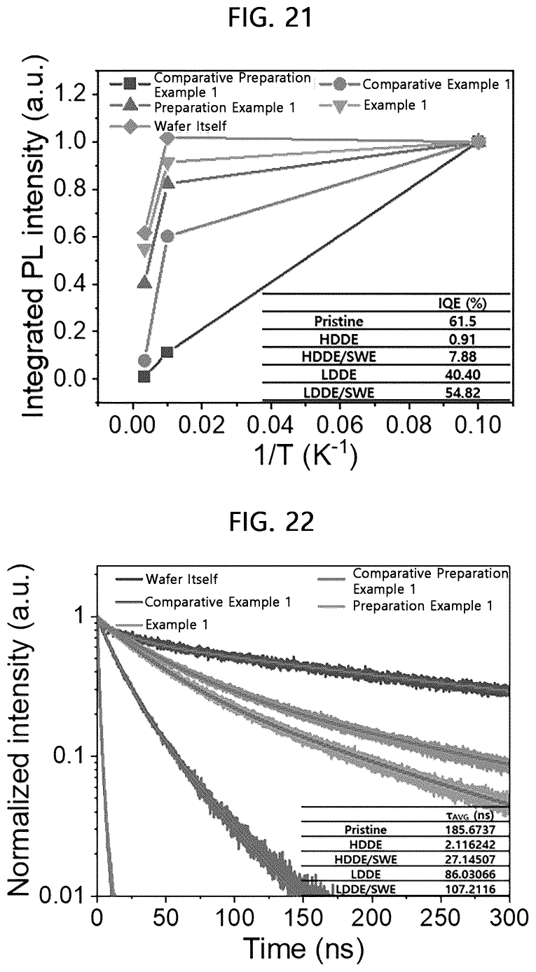

In addition, as shown in FIG. 21, the calculated internal quantum efficiency (IQE) of the sample subjected to the limited high-damage dry-etching is approximately 1.48%, and after performing the subsequent first recovery step involving wet-etching, the IQE reaches 14.0%, indicating that the first recovery step increases the internal quantum efficiency by about tenfold, although the absolute value remains low. In contrast, in the sample subjected to the recoverable low-damage dry-etching, the IQE reaches 40.4% even before the first recovery step, indicating that the recoverable low-damage dry-etching alone causes only a small decrease in internal quantum efficiency. After the first recovery step involving wet-etching, the IQE further increases to 54.8%, which is approximately 3.9 times higher than that of the wet-etched sample subjected to the limited high-damage dry-etching, confirming a remarkably high level of internal quantum efficiency.

In addition, to determine whether the efficiency difference of the LED devices obtained through the above-described etching methods is attributed to surface-defect characteristics, reference is made to FIG. 22. In the sample subjected to the recoverable low-damage dry-etching, the photoluminescence (PL) decay time increases from 106.9 ns after the dry-etching to 204.3 ns after the wet-etching first recovery step. In contrast, in the sample subjected to the limited high-damage dry-etching, the PL decay time is 3.1 ns after the dry-etching and 25.4 ns after the wet-etching first recovery step, indicating that the PL decay time remains relatively short even after the first recovery step. These results indicate that, in the LED device produced by the limited high-damage dry-etching, electrons excited by UV irradiation after the dry-etching are captured at energy levels corresponding to surface defects, where most participate in nonradiative decay and some in radiative decay leading to yellow emission. Consequently, the PL decay time of blue emission becomes extremely short. Therefore, although the PL decay time of the LED device obtained through the limited high-damage dry-etching can be slightly extended by the wet-etching first recovery step, the fact that it still remains short even after the first recovery step implies that the absolute amount of surface defects generated by the dry-etching is large, and that these surface defects are largely unrecoverable, indicating limited recoverability of the surface defects.

In addition, the structure produced by the recoverable low-damage dry-etching may exhibit a difference in average PL decay time characteristics compared with the structure produced by the limited high-damage dry-etching. Specifically, before the first recovery step (II) involving wet-etching described later, the structure produced by the recoverable low-damage dry-etching may have a longer average PL decay time measured at 300 K than that measured at 10 K. However, in the structure produced by the limited high-damage dry-etching, the average PL decay time measured at 300 K may be shorter than that measured at 10 K.

Accordingly, when the results of FIGS. 16 to 22 are collectively considered, in the case of the limited high-damage dry-etching, not only is the absolute amount of generated defects large, but the generated defects also exhibit limited recoverability, resulting in a structure having surface defects that are minimally recoverable or unrecoverable. In contrast, in the case of the recoverable low-damage dry-etching, the absolute amount of generated defects is small, and the generated defects exhibit high recoverability, allowing the recovery level to reach the defect level inherent to the wafer prior to the dry-etching, thereby producing a structure having surface defects with high recoverability. Furthermore, it can be understood that the manner in which the preceding dry-etching is performed, together with the subsequent recovery step, has a significant influence on the physical properties of the resulting LED device.

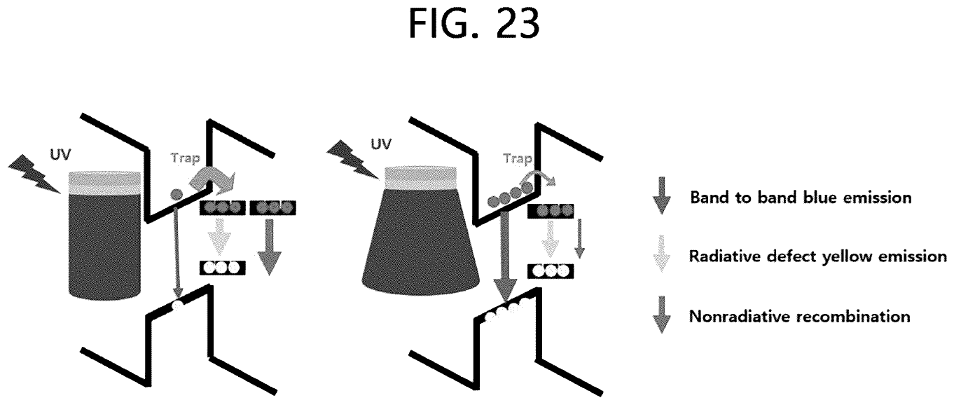

Meanwhile, the photoluminescence (PL) emission mechanism according to the dry-etching method will be described in detail with reference to FIG. 23. In the case of the limited high-damage dry-etching, even when the surface defects are reduced through the first recovery step (II) involving wet-etching described later, a large number of surface defects still remain as described above. Consequently, electrons excited by UV irradiation are trapped in the defect states, and the trapped electrons lead partly to yellow defect emission and mostly to loss due to nonradiative recombination by thermal (IR) processes. As a result, blue band-to-band emission decreases. In contrast, in the case of the recoverable low-damage dry-etching, the density of surface defects is significantly reduced during the first recovery step, so that yellow defect emission slightly decreases, whereas loss due to nonradiative recombination by thermal or IR processes is greatly reduced, and blue band-to-band emission can be considerably increased.

According to an embodiment of the present disclosure, the recoverable low-damage dry-etching performed through the above-described inductively coupled plasma-reactive ion etching (ICP-RIE) may be carried out at an etching rate such that the included angle (θ) formed between the etched sidewall (ss) of the structure 101a and the etched bottom surface (Is) of the structure continuous with the wafer after the dry-etching is 84° or less, and preferably 60° to 84°. By way of example, the etching rate may be 200 nm/min or less, preferably 150 nm/min or less, and more preferably 10 to 100 nm/min. Through such conditions, it is possible to reduce the amount of surface defects generated while significantly increasing the level of recoverable surface defects. If the etching rate is less than 10 nm/min, smooth etching may become difficult or the etching time may excessively increase, particularly when the etching depth is large. In contrast, if the etching rate exceeds 200 nm/min, physical etching becomes dominant, resulting in a structure subjected to the limited high-damage dry-etching.

In addition, the specific conditions of the ICP-RIE for the recoverable low-damage dry-etching may vary depending on the specific apparatus used. For example, the ICP power may be in the range of 50 to 350 W, and the RF power may be in the range of 10 to 100 W. More preferably, the ICP power may be in the range of 50 to 200 W, and the RF power may be in the range of 10 to 100 W.

In addition, as additional conditions required for the inductively coupled plasma-reactive ion etching (ICP-RIE), a chlorine-based process gas including BCl₃ and Cl₂ may be used. In this case, the flow rate of the process gas may be 0 to 100 sccm, or in another example, 0 to 60 sccm for BCl₃, and 0 to 100 sccm, or in another example, 0 to 60 sccm for Cl₂ (provided that both BCl₃ and Cl₂ are not 0 sccm simultaneously). These conditions may be advantageous for achieving the objectives of the present disclosure. In addition, the process gas may further include a nitrogen gas in addition to the chlorine-based gas, and the flow rate of the nitrogen gas may be 2 to 6 sccm. On the other hand, in one example, an inert gas, such as argon, may be excluded from the process gas. Furthermore, the process pressure may be 1 to 100 mT, and the DC bias voltage may be 100 to 200 V, which may be more favorable for achieving the objectives of the present disclosure. It is also noted that among the additional conditions required for the ICP-RIE, such as ICP power, RF power, and DC bias voltage, these parameters may be partially adjusted depending on the specific ICP-RIE apparatus used to achieve the same effects.

Next, as step (II), the plurality of structures produced by the dry-etching may undergo a first recovery step of wet-etching to remove surface defects present on the sidewalls of the structures produced by the dry-etching.

Referring to the above step (I), near the surface of the etched plane during the dry-etching, various types of surface defects may be present, including an amorphous region, group-III element deficiencies such as Ga vacancies, and mis-bonded configurations such as Ga—O and/or Ga—Ga bonds. These surface defects significantly degrade the light-emission efficiency of the resulting LED device, and even in the preferred case of the recoverable low-damage dry-etching, the defect level may still increase relative to that inherent in the wafer itself. Accordingly, as step (II), a first recovery step of wet-etching may be performed on the dry-etched wafer 100g to remove the dead volume generated on the structure 101a formed by the dry-etching, thereby obtaining a first-recovered wafer 100h. In addition, as illustrated in FIG. 14, even when the etched surface is formed in a tapered shape that is inclined relative to the main surface of the wafer during the dry-etching, the subsequent wet-etching step (II) may enable the lower portion and the etched sidewall of the structure to be etched so as to form an angle close to a right angle.

Preferably, the step (II) may be performed such that the included angle (e) formed between the sidewall (ss) of the structure subjected to the wet-etching and the bottom surface (Is) of the structure continuous with the wafer is 85° or more, and any wet-etching condition that enables the formation of such an included angle may be adopted without limitation. For example, the wet-etching may be performed by immersing the wafer in a wet-etching solution containing an ammonium salt or potassium with a hydroxyl group at a temperature of 60 to 100° C. for 5 to 30 minutes, which may be advantageous for obtaining an LED device exhibiting excellent light-emission efficiency.

In addition, according to an embodiment of the present disclosure, in the LED structure subjected to step (II), the percentage of the peak area of the Ga-vacancy-related defect mode located at 687 cm⁻¹ with respect to the peak area of the GaN A₁(LO) mode located at 746.62 cm⁻¹, based on Raman spectral analysis of the sidewall of the etched structure, may be 8% or less, indicating that surface defects are significantly reduced. Specifically, referring to FIG. 16, when the first recovery step involving wet-etching is performed after the limited high-damage dry-etching, the percentage of the peak area of the Ga-vacancy-related defect mode is about 11%. In contrast, when the first recovery step involving wet-etching is performed after the recoverable low-damage dry-etching, the percentage of the peak area of the Ga-vacancy-related defect mode decreases to about 4.8%, confirming that the amount of Ga-vacancy defects remaining on the sidewall of the recovered LED structure is substantially reduced, thereby enabling the acquisition of an LED device exhibiting excellent light-emission efficiency.

In addition, based on Ga 3d bonding analysis by XPS spectroscopy performed on the etched sidewall (ss) of the LED, the ratio of Ga—O bonds may be less than +30% of the Ga—O bond ratio inherent to the wafer itself. In other words, in the case of the recoverable low-damage dry-etching, the Ga—O bonds produced by the dry-etching can be restored, through the subsequent first recovery step involving wet-etching, to the defect level inherent to the wafer prior to the dry-etching, or the defects may even be further improved. Specifically, referring to FIGS. 17 and 18, in the case of the recoverable low-damage dry-etching, the ratio of Ga—O bonds, which correspond to defects, is improved to 9%, lower than the 11% inherent to the wafer itself. In contrast, in the case of the limited high-damage dry-etching, although the Ga—O bond ratio decreases from 22% after the dry-etching to 16% after the first recovery step involving wet-etching, this still represents a 45.5% increase compared with the 11% Ga—O bond ratio inherent to the wafer, indicating that an LED device having significantly degraded properties compared with the wafer itself is obtained.

In addition, referring to FIGS. 17 and 18, the Ga—Ga bonds, which correspond to defects other than the Ga—O bonds, are restored to a level of about 12% after the first recovery step following the recoverable low-damage dry-etching, which is slightly higher than the inherent ratio of 9% in the wafer itself, indicating that the defects are recovered to a level similar to or slightly higher than the defect level of the wafer prior to etching. In contrast, after the first recovery step following the limited high-damage dry-etching, the Ga—Ga bond ratio reaches 23%, which is significantly higher than the inherent ratio of 9% in the wafer itself, confirming that it is difficult to realize an LED device having a defect level comparable to that of the wafer.

Meanwhile, as described above, when the recoverable low-damage dry-etching of step (1) is followed by the first recovery step of step (II), most of the defects can be substantially removed and recovered. However, some defects may still be difficult to restore to the level inherent to the wafer itself. In addition, due to the increase in dangling bonds, strain may occur on the sidewall of the etched plane.

Accordingly, according to an embodiment of the present disclosure, after the first recovery step of step (II), a second recovery step ((i) of FIG. 12) of irradiating the wet-etched structure (100h in FIG. 12) with UV light may be further performed. Through this process, the remaining defects and dangling bonds can be recovered so that the internal quantum efficiency reaches that of the wafer itself before etching.

Specifically, referring to FIG. 24, when UV irradiation is applied to the structure that has undergone the first recovery step involving wet-etching after the recoverable low-damage dry-etching, the remaining defects and dangling bonds are passivated, resulting in a steady increase in the intensity of the photoluminescence (PL) emission peak with the duration of UV irradiation. Meanwhile, the increase in PL emission peak intensity caused by the passivation of the residual defects and dangling bonds may occur over an extended period until the passivation is completed, and by way of example, the passivation of defects may reach saturation after approximately 12 hours of UV irradiation.

Meanwhile, in the second recovery step, UV irradiation does not necessarily recover the residual defects or dangling bonds on all dry-etched surfaces subjected to different conditions. That is, even when the structure subjected to the above-described limited high-damage dry-etching undergoes the first recovery step through wet-etching and is subsequently exposed to UV irradiation in the second recovery step, little or no recovery of defects may occur.

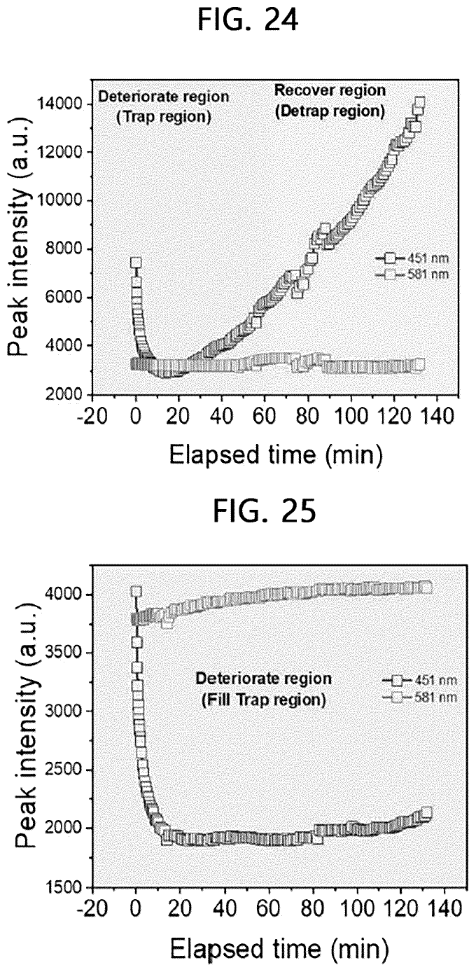

Specifically, referring to FIG. 25, it can be seen that in the structure subjected to the limited high-damage dry-etching followed by the first recovery step, almost no change occurs in the light-emission characteristics even when UV irradiation is applied. In contrast, referring to FIG. 24, the structure subjected to the recoverable low-damage dry-etching followed by the first recovery step exhibits an improvement in light-emission characteristics through the second recovery step involving UV irradiation.

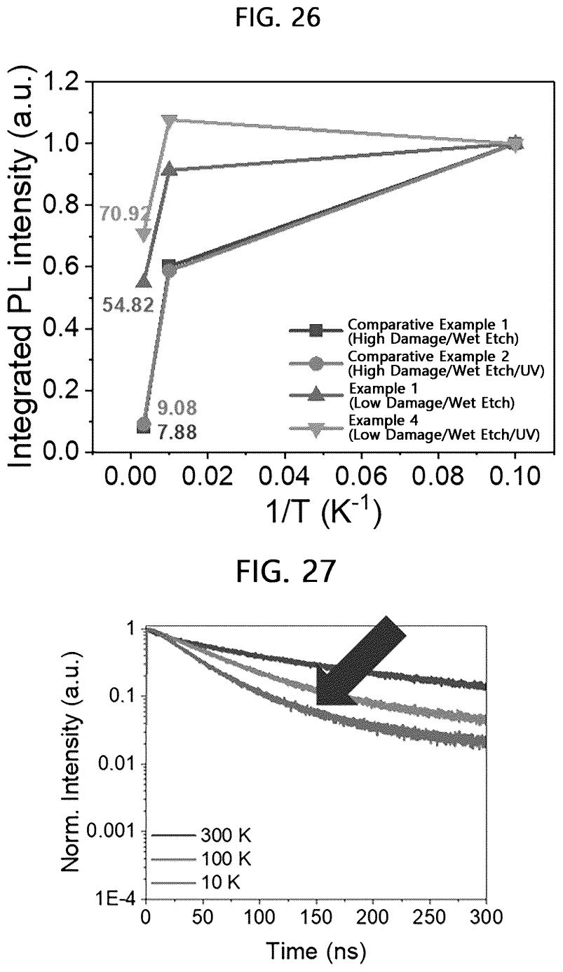

In addition, referring to FIG. 26, when the internal quantum efficiency is calculated by measuring photoluminescence (PL) at low temperature (10 K) and at room temperature (300 K) for the LED devices obtained after the second recovery step involving UV irradiation, it is found that the LED device obtained through the limited high-damage dry-etching and wet-etching exhibits an internal quantum efficiency of 15.8% after UV irradiation, which is slightly decreased or nearly unchanged compared with that before UV irradiation. In contrast, the LED device obtained through the recoverable low-damage dry-etching and wet-etching exhibits an internal quantum efficiency of 71.1% after UV irradiation, representing an improvement of about 30% from 54.8% before UV irradiation, and it can be confirmed that the internal quantum efficiency approaches that of the wafer itself prior to etching.

Meanwhile, in the second recovery step, UV irradiation may induce additional defects in certain defect states that have been recovered during the first recovery step, depending on the dry-etching method employed. That is, in the case of the limited high-damage dry-etching, some of the defects generated therein may be further increased after the second recovery step, thereby reducing the total amount of recovery achieved after the first and second recovery steps, even though the first recovery step initially restored them. In contrast, in the case of the recoverable low-damage dry-etching, even if certain defects generated therein are not further recovered through the second recovery step, the level of recovery achieved in the first recovery step can be maintained.

Accordingly, according to an embodiment of the present disclosure, the LED structure subjected to the second recovery step may satisfy, based on Raman spectral analysis of the sidewall of the etched structure, a percentage of the peak area of the Ga-vacancy-related defect mode located at 687 cm⁻¹ with respect to the peak area of the GaN A₁(LO) mode located at 746.62 cm 1 that remains the same as that of the LED structure subjected to the first recovery step (step (II)), i.e., 8% or less. This demonstrates that performing the second recovery step can prevent a reduction in the overall degree of recovery and a corresponding decrease in material improvement that could otherwise result from the generation of additional defects.

Specifically, referring to FIG. 16, when the first recovery step involving wet-etching is performed after the limited high-damage dry-etching, the percentage of the peak area of the Ga-vacancy-related defect mode located at 687 cm⁻¹ with respect to the peak area of the GaN A₁(LO) mode located at 746.62 cm⁻¹ in the Raman spectrum is 11.0%, and after the second recovery step involving UV irradiation, the value increases to 13.8%, indicating that the defects are instead aggravated. In contrast, when the first recovery step involving wet-etching is performed after the recoverable low-damage dry-etching, the percentage of the peak area of the Ga-vacancy-related defect mode located at 687 cm 1 with respect to the peak area of the GaN A₁(LO) mode located at 746.62 cm⁻¹ in the Raman spectrum is 4.8%, and the value remains at 4.8% even after the second recovery step involving UV irradiation, demonstrating that a reduction in the recovery level is effectively prevented.

In addition, this interpretation is also supported by the results shown in FIGS. 17 and 18. Specifically, when the Ga 3d peak in the XPS spectrum is measured and the spectrum is deconvoluted into Ga—N, Ga—Ga, and Ga—O bonds to quantify their relative amounts, it is found that, in the structure formed by the limited high-damage dry-etching, the ratio of Ga—O bonds increases to 19% after the first and second recovery steps, which is an increase of approximately 72.7% compared with the 11% inherent to the wafer itself, and the ratio of Ga—Ga bonds likewise increases from 9% in the wafer to 21%, corresponding to an increase of approximately 133.3%. In contrast, in the structure formed by the recoverable low-damage dry-etching, after the first and second recovery steps, the ratio of Ga—O bonds remains nearly unchanged at 11%, the same as the wafer itself. Accordingly, it can be confirmed that, in the case of the recoverable low-damage dry-etching followed by the first and second recovery steps, the Ga—O bonds are restored to the wafer level, which further indicates that the Ga—O bonds constitute one of the main causes of surface defects.

In addition, referring to FIG. 27, the LED device obtained through the recoverable low-damage dry-etching (step (I)), the first recovery step involving wet-etching, and the second recovery step involving UV irradiation may exhibit an average photoluminescence (PL) decay time that remains the same or becomes longer as the temperature increases, and preferably becomes longer. For example, the average decay time measured at room temperature (300 K) may be longer than that measured at low temperature (10 K), and more preferably, the average decay time measured at 300 K may be 30% or more longer than that measured at 10 K, thereby achieving excellent light-emission efficiency. Furthermore, the LED structure after the first recovery step may exhibit a longer average decay time at 300 K than the LED structure before the first recovery step.

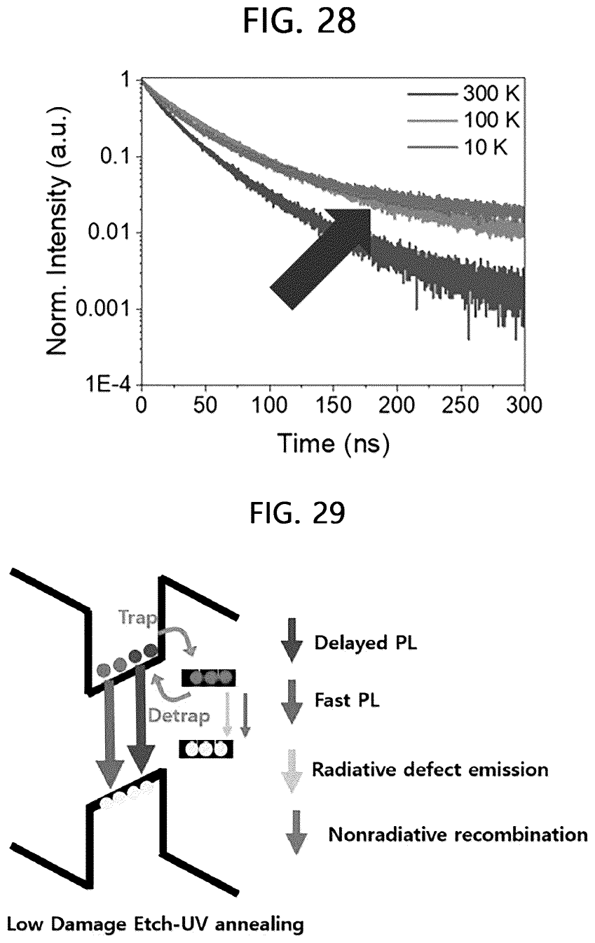

In contrast, as shown in FIG. 28, the LED device obtained through the limited high-damage dry-etching, the first recovery step involving wet-etching, and the second recovery step involving UV irradiation exhibits a shorter average photoluminescence (PL) decay time as the temperature increases from low temperature (10 K) to room temperature (300 K) despite the two successive recovery steps. This behavior is consistent with the emission mechanism of light-emitting materials containing a high density of defects.

The results shown in FIGS. 27 and 28 are attributed to a mechanism in which prolonged UV irradiation passivates surface defects, thereby forming shallow non-quenching traps. Carriers are repeatedly trapped and detrapped through these traps, resulting in delayed luminescence. Although the significant reduction in defect density is partly due to the recoverable low-damage dry-etching and wet-etching, the reversal of the decay-time trend with temperature indicates that the remaining defects and dangling bonds are reduced by UV passivation and converted into non-quenching traps.

Specifically, as shown in FIG. 18, prolonged UV irradiation passivates surface defects, thereby reducing defect-related radiative and non-radiative recombination and promoting the detrapping of electrons back into the conduction band. In this case, some of the electrons excited by the UV irradiation undergo rapid emission through the conventional electron-hole recombination process, producing a peak with a short decay time. Meanwhile, the remaining electrons excited by UV irradiation are repeatedly trapped and detrapped through shallow and deep non-quenching traps, and some or all of the electrons that return to the conduction band gradually emit light, resulting in the coexistence of a delayed-emission peak with a long decay time and a peak with a short decay time. Consequently, the overall effect is an extension of the average decay time. Therefore, the phenomenon in which the average decay time at room temperature (300 K) becomes longer than that at low temperature (10 K) demonstrates that the second recovery step involving UV irradiation passivates the surface defects originating from dangling bonds into non-quenching traps, thereby facilitating trap-detrapping transitions at room temperature.

Meanwhile, in the second recovery step, UV irradiation chemically adsorbs water molecules (H₂O) onto the dangling bonds on the etched sidewall, dissociating them into —OH and —H groups. This process alleviates the strain caused by the dangling bonds and enables electrons trapped in shallow and deep traps to be retrapped into the conduction band, thereby allowing them to participate in light emission and increasing the light-emission efficiency.

In addition, the UV used in the second recovery step may have a wavelength of 250 to 400 nm and may be irradiated at an intensity of 1 mW to 100 W for a duration of 0.1 to 48 hours, which may be advantageous for achieving the objectives of the present disclosure.

Next, the structure irradiated with UV light may further undergo a step of forming a protective film (80) ((j) and (k) of FIG. 12) to protect the sidewalls on which the dead volumes have been removed and the remaining defects have been passivated. The step of forming the protective film 80 may include depositing a protective-film material onto the wafer on which the UV-irradiated structures 101a are formed so as to surround the exposed surfaces of the respective structures 101a with a protective film 80a having a predetermined thickness ((j) of FIG. 12), and then removing the protective film deposited on the upper surface S₁ of the first conductive semiconductor layer 10 between adjacent structures 101a and the protective film formed on the upper surface of the electrode layer 40, thereby exposing the upper surface S₁ of the first conductive semiconductor layer 10 and the electrode layer 40 between the structures 101a ((k) of FIG. 12). The protective-film material may include at least one selected from the group consisting of silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), lanthanum oxide (La₂O₃), scandium oxide (Sc₂O₃), titanium dioxide (TiO₂), aluminum nitride (AlN), and gallium nitride (GaN). In addition, the protective film 80 formed by depositing the protective-film material may have a thickness of 5 to 100 nm, and more preferably 30 to 100 nm.

Thereafter, as step (III), a step of separating the plurality of structures from the wafer may be performed.

The plurality of structures may be separated from the wafer by a known method, and the present disclosure is not particularly limited thereto. For example, the plurality of structures 101a may be separated from the wafer through the removal of a sacrificial layer or separation layer provided in the wafer itself. Alternatively, the plurality of structures 101a may be separated by a method disclosed in Korean Patent Laid-Open Publication No. 10-2021-0132920 by the inventors of the present disclosure, in which the lower side portions of the structures 101a are laterally wet-etched parallel to the main surface of the wafer and then separated using a cutting mechanism or an adhesive separation film. Alternatively, the plurality of structures 101a may be separated from the wafer by applying a physical force such as ultrasonic waves after the lateral wet-etching. Alternatively, according to Korean Patent Laid-Open Publication No. 10-2022-0096608 by the inventors of the present disclosure, the plurality of structures 101a may be separated by forming a plurality of pores through an electrochemical process in the upper surface S₁ of the first conductive semiconductor layer 10 between the structures 101a and in a portion of the first conductive semiconductor layer 10 beneath the structures 101a, immersing the wafer in a bubble-generating solution, and applying ultrasonic waves, such that bubbles generated and expanded within the pores collapse and provide energy to separate the plurality of structures 101a from the first conductive semiconductor layer 10 having the pores formed therein. Through this process, an LED device assembly 100 including a plurality of individually separated LED devices 101 can be obtained.

In addition, in order to separate the plurality of structures from the wafer, well-known methods other than the above-described separation methods proposed by the inventors, such as laser lift-off, chemical lift-off, and mechanical lift-off, may also be employed. The present disclosure is not particularly limited to the method of separating LED structures having an area of 100 μm² or less.

The LED device 101 included in an embodiment of the present disclosure and obtained through the above-described manufacturing method exhibits a characteristic in which the average decay time measured at 300 K is equal to, or preferably longer than, the average decay time measured at 10 K. This characteristic results from the substantial removal of surface defects generated during the dry-etching process, as well as the passivation of residual defects and dangling bonds, thereby facilitating trapping-detrapping at room temperature. Accordingly, it can be indirectly demonstrated that the internal quantum efficiency of the individual LED device 101 approaches that of the wafer 101a from which the LED device 101 originates.

In addition, in the light emission of the LED device 101 measured at 300 K, the contribution of delayed luminescence originating from shallow and deep traps may be greater than that of bandgap emission, and more preferably, may be at least twice as great. This explains the improvement in efficiency attributable to delayed luminescence.

The LED device 101 to be implemented may have a thickness of 10 μm or less, for example 0.5 to 5 μm, or 0.5 to 2.0 μm. In addition, the planar area of the LED device 101, that is, the area of a surface perpendicular to the thickness direction, may be 100 μm² or less, or 10 μm² or less, but is not limited thereto. The shape of the plane perpendicular to the thickness direction may be a polygon such as a triangle, square, or rectangle, or a closed curve such as a circle or an ellipse, and the present disclosure is not particularly limited thereto.

In addition, the first conductive semiconductor layer 10 of the LED device 101 may have a thickness of 0.5 to 9.0 μm but is not limited thereto.

Referring to FIG. 2, an LED device 101 may be mounted such that a first surface or a second surface thereof is in contact with upper surfaces of two adjacent lower electrodes 211 and 212. Alternatively, referring to FIG. 7, an LED device 104 may be mounted such that a first surface or a second surface thereof is in contact with an upper surface of one of the lower electrodes 211, 212, and 213.

Referring to FIG. 2, an LED device 101 may be mounted such that a first surface or a second surface thereof is in contact with upper surfaces of two adjacent lower electrodes 211 and 212. Alternatively, referring to FIG. 7, an LED device 104 may be mounted such that a first surface or a second surface thereof is in contact with an upper surface of one of the lower electrodes 211, 212, and 213. In addition, as illustrated in FIGS. 2 and 7, a passivation layer 600 may be formed between the lower electrode lines 200 and 200′ and the upper electrode line 300 to fix and insulate the LED devices 101 and 104 and to provide a surface on which the upper electrode line 300 is to be formed. The passivation layer 600 may be formed of any conventional passivation material commonly used in electrical and electronic components without particular limitation. For example, the passivation layer 600 may be deposited by a plasma-enhanced chemical vapor deposition (PECVD) process using a passivation material such as SiO₂ or SiNₓ; by a metal-organic chemical vapor deposition (MOCVD) process using a material such as AlN or GaN; or by an atomic layer deposition (ALD) process using a material such as Al₂O₃, HfO₂, or ZrO₂. Meanwhile, the passivation layer 600 should be formed so as not to cover the upper surfaces of the LED devices 101 and 104. To this end, the passivation layer may be deposited to a thickness that does not cover the upper surfaces, or alternatively, it may first be deposited to cover the upper surfaces and then dry-etched so that the upper surfaces of the LED devices 101 and 104 are exposed.

In addition, the upper electrode line 300 includes a color conversion layer 700 in which blue, green, and red color conversion layers 713, 711, and 712 are patterned such that, for each of the plurality of sub-pixel regions S₁, S₂, S₃, a sub-pixel region independently emits one of blue, green, and red colors.

In the full-color LED display 1000, 1000′ according to the first embodiment, the LED devices 101 and 104 provided in the sub-pixel regions S₁, S₂, S₃ may emit light having a chromatic color of blue, white, or UV. In this case, a color conversion layer 700 capable of converting the emitted light into light of another color to display a color image is provided above the sub-pixel regions S₁, S₂, S₃. In addition, the blue color conversion layer 713, the green color conversion layer 711, and the red color conversion layer 712 may each be a known color conversion layer including a phosphor layer or quantum dots configured to convert the wavelength of light emitted from the LED devices 101, 104 so that the light transmitted through the color conversion layer exhibits blue, green, and red colors, respectively. The present disclosure is not particularly limited thereto. Meanwhile, when the LED devices 101, 104 are blue-emitting devices, the blue color conversion layer 713 may be omitted, and in such a case, the color conversion layer 700 may include only the green color conversion layer 711 and the red color conversion layer 712.

Preferably, in order to further enhance color purity and improve color reproducibility, and to increase the front-emission efficiency of the color-converted light—such as green or red light—by directing rear emission from the color conversion layer toward the front, a short-pass filter (not illustrated) may be further provided above the sub-pixel regions S₁, S₂, S₃. In addition, the color conversion layer 700 may be formed on a region of an upper portion of the short-pass filter.

Preferably, a long-pass filter (not shown) may further be provided above the green color conversion layer 711 and the red color conversion layer 712. The long-pass filter functions to prevent a reduction in color purity that may occur when blue light emitted from the LED device 101 is mixed with the color-converted green and red light. The long-pass filter may be formed on at least a part or the entirety of the upper portions of the green and red color conversion layers, and preferably, it may be formed only on the green and red color conversion layers.

In addition, a protective layer 800 for protecting the above-described color conversion layer 700 may further be provided. The protective layer 800 may appropriately employ a protective layer commonly used in conventional displays having a color conversion layer, and the present disclosure is not particularly limited thereto.

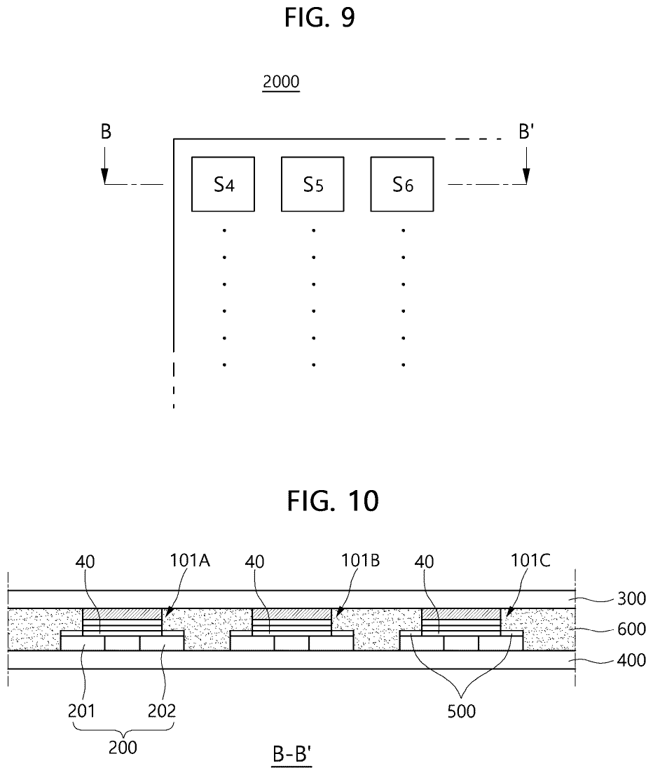

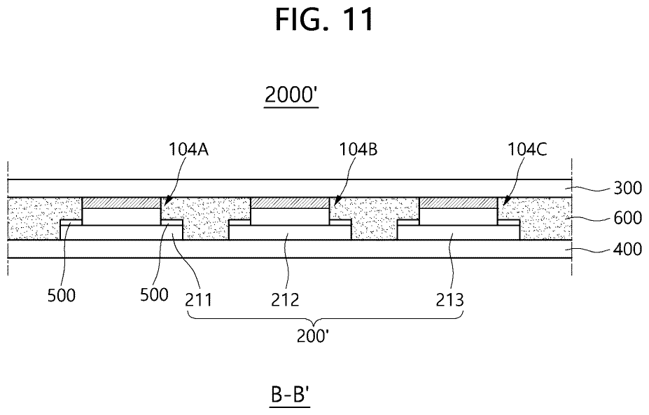

Next, referring to FIGS. 9 to 11, a full-color LED display 2000, 2000′ according to a second embodiment of the present disclosure is a display that implements color using LED devices having three chromatic colors of RGB light. The display includes a plurality of sub-pixel regions S₄, S₅, S₆, which respectively correspond to blue, green, and red sub-pixel regions. Each of the sub-pixel regions S₄, S₅, S₆ includes a lower electrode line 200, 200′; a plurality of LED devices 101A/104A, 101B/104B, 101C/104C, each independently emitting one of blue, green, and red light; and an upper electrode line 300 disposed on the plurality of LED devices 101A/104A, 101B/104B, 101C/104C. The plurality of LED devices 101A/104A, 101B/104B, 101C/104C have first and second surfaces opposite to each other in the thickness direction in which multiple layers 10, 20, 30, and 40 are stacked, and remaining sidewalls. In each sub-pixel region S₄, S₅, S₆, either the first or the second surface of the device is mounted to contact the lower electrode line 200, 200′. As illustrated in FIG. 10, an LED device 101A, 101B, 101C may be mounted such that a first surface or a second surface thereof contacts upper surfaces of two adjacent lower electrodes 211, 212. Alternatively, referring to FIG. 11, an LED device 104A, 104B, 104C may be mounted such that a first surface or a second surface thereof contacts an upper surface of one of the lower electrodes 211, 212, 213.

In addition, the LED devices 101A, 101B, 101C, 104A, 104B, 104C may have a thickness of 10 μm or less, a cross-sectional area perpendicular to the thickness direction of 100 μm² or less, and an average decay time measured at 300 K that is equal to or longer than that measured at 10 K, thereby implementing a display having excellent light-emission efficiency. In this case, the LED devices may include blue LED devices 101A and 104A, green LED devices 101B and 104B, and red LED devices 101C and 104C to implement color. The chromatic colors of blue, green, and red may have wavelength ranges known as chromatic colors of LEDs employed in displays, and the present disclosure is not particularly limited thereto.

Meanwhile, in the second embodiment, except for the chromatic color, the LED devices 101A, 101B, 101C, 104A, 104B, 104C are the same as those described for the LED devices in the first embodiment described above, and therefore, detailed descriptions of the specific technical features and manufacturing methods thereof will be omitted. In addition, in the second embodiment, the descriptions of the lower electrode lines 200, 200′, the upper electrode line 300, and the passivation layer 600 are also the same as those in the first embodiment, and thus detailed descriptions thereof will be omitted.

The full-color displays 1000, 1000′, 2000, and 2000′ according to the above-described first and second embodiments may be implemented through the following processes: (1) dispensing a solution containing a plurality of LED devices onto a lower electrode line on which a plurality of sub-pixel regions are formed; (2) self-aligning the LED devices introduced into each sub-pixel region on the lower electrode line such that either a first surface or a second surface of each LED device becomes a mounting surface; and (3) forming an upper electrode line on the plurality of self-aligned LED devices.

In the manufacturing method of the full-color LED display 2000, 2000′ according to the second embodiment, the method is the same as the manufacturing method of the full-color LED display 1000 according to the first embodiment, except that each of the LED devices 101A, 101B, 101C, 104A, 104B, 104C introduced has different chromatic colors—such as blue, green, and red—and that the LED devices included in the LED solution introduced into each sub-pixel region S₄, S₅, S₆ consist of LED devices having only one of the three chromatic colors. Accordingly, a separate color conversion layer for implementing color may be omitted. Therefore, the following description of the specific manufacturing process of the full-color display will be made with reference to the first embodiment.

First, as step (1) according to the present disclosure, a step of dispensing a dispersion containing a plurality of LED devices 101, 104 that emit the same chromatic color onto a lower electrode line 200, 200′ having a plurality of sub-pixel regions S₁, S₂, S₃ formed thereon is performed.

The dispersion containing the LED devices 101, 104 is a solution in which the LED devices 101, 104 are dispersed in a solvent, and the dispersed LED devices 101, 104 may all emit the same chromatic color.

In addition, the solvent not only serves as a dispersion medium for dispersing the LED devices 101, 104, but also functions to facilitate the movement of the LED devices 101, 104 to enable easier self-alignment on the lower electrode line 200, 200′. The solvent may be any solvent that does not physically or chemically damage the LED devices 101, 104 and, preferably, improves the dispersibility of the LED devices 101, 104 without limitation.

In addition, the solvent may include one or more of water and organic solvents. At this time, the solvent may be selected to assist the specific self-alignment method performed in step (2) described below.

For example, when the self-alignment method performed in step (2) is dielectrophoresis, the solvent may have an appropriate dielectric constant such that the LED devices 101, 104 dispersed in the solvent experience a dielectrophoretic force attracting them toward the lower electrode line 200. Specifically, when the dielectrophoresis method is employed, the solvent may have a dielectric constant of 10.0 or more, or in another example, 30.0 or less, or more specifically, 28.0 or less. This allows step (2) to be smoothly performed using dielectrophoresis and is advantageous for minimizing mounting defects of the LED devices. As a specific example, solvents satisfying the above dielectric constant may include acetone and isopropyl alcohol.

In addition, when the self-alignment method performed in step (2) described below is electro-osmosis, the solvent may have a dielectric constant suitable for driving and positioning LED devices 104 onto the upper surfaces of one of the lower electrodes 211, 212, 213 within the lower electrode line 200′ while increasing the mounting ratio, that is, the ratio of LED devices 104 that are individually mounted with either their first or second surface on the upper surface of the lower electrode among all LED devices 104. Specifically, in order to achieve such a high mounting ratio, the dielectric constant of the solvent may be 5 or more, preferably 14 or more, more preferably 23 or more, and even more preferably 33 or more. If the dielectric constant of the solvent is less than 5, the ratio of LED devices moving onto and being seated on the upper surfaces of the lower electrodes 211, 212, 213 may decrease; or even if the ratio of LED devices seated on the upper surfaces of the lower electrodes 211, 212, 213 increases, the proportion of LED devices whose sidewalls contact the upper surfaces of the lower electrodes instead of their first or second surface—thus failing to emit light—may significantly increase, resulting in reduced luminance of the implemented sub-pixel regions and, consequently, of the full-color LED display. In addition, the dielectric constant of the solvent may be 50 or less. If the dielectric constant of the solvent exceeds 50, the ratio of LED devices that move onto and are seated on the upper surfaces of the lower electrodes or that can be properly driven may rather decrease, and there is a risk of damage to the lower electrodes.

In addition, when the self-alignment method performed in step (2) described below is electro-osmosis, the solvent may have a viscosity of 50 cP or less, and preferably 5 to 15 cP, in order to enhance the dominance of the electro-osmotic pressure applied to the LED devices 104 and thereby increase the ratio of LED devices 104 that move and become aligned on the upper surfaces of the respective lower electrodes 211, 212, 213 shown in FIG. 7. If the viscosity of the solvent exceeds 50 cP, the ratio of LED devices that move and align on the upper surfaces of the lower electrodes relative to the total number of LED devices introduced may be insufficient. Conversely, if the viscosity is less than 5 cP, the solvent may evaporate too quickly, resulting in an insufficient or absent amount of solvent during the movement and alignment of the LED devices, making it difficult to secure sufficient process time for proper movement and alignment. Here, the viscosity refers to a value measured at 25° C. using a Brookfield viscometer, and since the specific measurement method may follow known techniques, a detailed description thereof will be omitted.

In addition, the solution containing the LED devices 101, 104 may contain the LED devices 101, 104 in an amount of 0.01 to 99.99 wt %, and the present disclosure is not particularly limited thereto. The solution may be in the form of an ink or a paste.

Meanwhile, in step (1), the solution may be applied onto the lower electrode line 200 by a known method, and for mass production, a known coating apparatus such as a printer device (e.g., an inkjet printer) or a bar coater may be used. In addition, to be used in such a printer device, the solution containing the LED devices may be implemented as an ink composition suitable for the printer device and its method. In this case, the type of solvent may be appropriately selected in consideration of physical properties such as the viscosity of the solvent, and the composition may further include additives that are typically added to compositions used in such printing methods and devices. The present disclosure is not particularly limited thereto.

Meanwhile, although step (1) has been described as involving the introduction of the LED devices 101, 104 in a state of being mixed with a solvent, cases in which the LED devices are first introduced onto the lower electrode line 200 and the solvent is subsequently introduced, or vice versa, in which the solvent is first introduced and then the LED devices are introduced, are also included in step (1), insofar as the result is the same as introducing the solution.

In addition, the solution containing the LED devices may be processed such that at least one or two or more LED devices 101, 104 are included in each of the plurality of sub-pixel regions S₁, S₂, S₃. When the solution is processed such that two or more LED devices are included per sub-pixel region, defective pixels caused by a sub-pixel region S₁, S₂, S₃ failing to emit light due to a defective LED device or a mounting defect can be prevented.

Meanwhile, on the lower electrode line 200, 200′, a partition wall (not shown) having sidewalls surrounding each of the sub-pixel regions S₁, S₂, S₃ at a predetermined height may further be provided to prevent the introduced LED devices 101, 102, 103, 104 or the solution containing them from flowing out of the intended regions, that is, the respective sub-pixel regions S₁, S₂, S₃ that are not physically partitioned, and to concentrate and arrange the LED devices 101, 102, 103, 104 within each sub-pixel region. The solution containing the LED devices may be dispensed inside the partition wall. The partition wall may be formed of an insulating material so as not to cause electrical influence when the LED devices are driven in the final display in which the LED devices are mounted. Preferably, the insulating material may include one or more of inorganic insulating materials such as silicon dioxide (SiO₂), silicon nitride (Si₃N₄), aluminum oxide (Al₂O₃), hafnium oxide (HfO₂), yttrium oxide (Y₂O₃), and titanium dioxide (TiO₂), and various transparent polymer insulating materials. The partition wall may be fabricated by forming the insulating material to a predetermined height on the lower electrode line 200 and then patterning and etching the insulating material so that sidewalls surrounding the respective sub-pixel regions S₁, S₂, S₃ are formed.

At this time, when the partition wall is made of an inorganic insulating material, it may be formed by any one of chemical vapor deposition, atomic layer deposition, vacuum deposition, e-beam deposition, and spin coating. When the material is a polymer insulating material, the partition wall may be formed by a coating method such as spin coating, spray coating, or screen printing. The patterning of the partition wall may be performed using photolithography employing a photosensitive material, or by known nanoimprinting, laser interference lithography, or electron-beam lithography. The height of the partition wall thus formed may be at least one-half of the thickness of the LED device and, preferably, 0.1 to 100 μm, more preferably 0.3 to 10 μm, as a thickness that does not affect subsequent processes. The etching process may be selected according to the material of the insulating material, and may be performed by a wet-etching method or a dry-etching method. Preferably, the dry-etching method may be one or more of plasma etching, sputter etching, reactive ion etching, and reactive ion beam etching.

Next, as step (2), a step of self-aligning the LED devices 101, 104 introduced into each of the sub-pixel regions S₁, S₂, S₃ on the lower electrode line 200 such that either the first surface or the second surface of each LED device becomes a mounting surface is performed.

The LED devices 101, 104 disposed on the lower electrode line 200 may be self-aligned by a known method. For example, the LED devices 101 may be self-aligned by one or more of dielectrophoretic force, electro-osmotic pressure, magnetic force, van der Waals force, chemical bonding such as covalent bonding or ionic bonding, and free sedimentation in the solvent.

In this case, depending on the selected self-alignment method, the LED devices may have appropriate shapes, sizes, materials, and/or structures. In addition, these parameters of the LED devices may affect the sedimentation-preventing capability of the LED devices when implemented in an ink composition. Accordingly, the appropriate self-alignment method may be determined in consideration of the shape and size of the selected LED devices, or conversely, the factors such as the size of the LED devices may be appropriately adjusted in consideration of the selected self-alignment method.

With respect to the LED devices and self-alignment technologies applicable to step (2), Korean Patent Application Nos. 10-2020-0050885, 10-2020-0189203, 10-2021-0143366, 10-2021-0181879, 10-2022-0075384, 10-2022-0086123, 10-2023-0178751, and 10-2023-0178753, filed by the inventors of the present disclosure, are incorporated herein by reference as references relating to the present disclosure, and a detailed description thereof will be omitted.

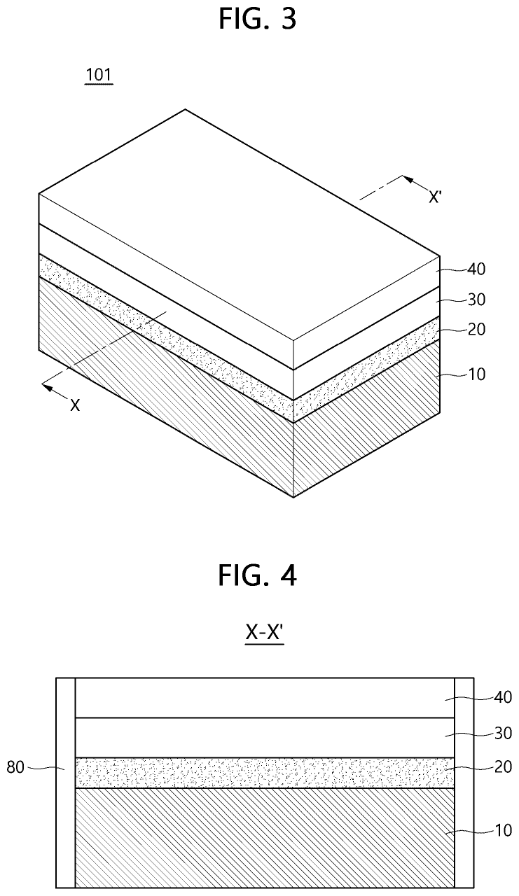

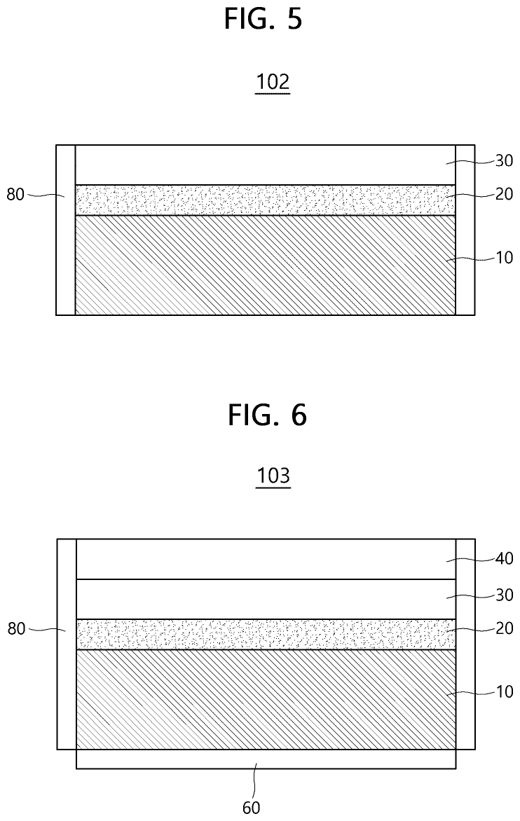

By way of example, to be more suitable for dielectrophoretic force, the LED devices may have an elongated shape in one direction, as illustrated in FIGS. 3 to 6. For example, LED devices 101, 102, 103 may have an aspect ratio (a/b), which is a ratio of the length (a) of a major axis to the longer one (b) of a width in the y-axis direction or a thickness in the z-axis direction, of 2.5 or more, or 3.0 or more. In this case, the LED devices may be more advantageous for self-alignment by dielectrophoretic force compared to other shapes. In addition, to facilitate self-alignment by dielectrophoretic force, one side of the LED devices 101, 103 opposite in the thickness direction may further include a selective alignment layer such as the electrode layer 40. The electrode layer 40 may cause a difference in electrical conductivity and/or dielectric constant relative to the first conductive semiconductor layer 10, thereby allowing a desired surface—either the first or second surface—to serve as a mounting surface during selective self-alignment. In another example, as illustrated in FIG. 6, to further control the difference in electrical conductivity and/or dielectric constant between the two opposing surfaces in the thickness direction, an LED device 103 may include a selective alignment layer such as the electrode layer 40 on one side, and a selective alignment suppression layer 60 on the opposite side, for example, on the non-mounting side, that is, the side contacting the upper electrode line 300. By way of example, the selective alignment layer such as the electrode layer 40 may be made of a material having a higher electrical conductivity than the first conductive semiconductor layer 10, and any electrode layer commonly used in LED devices may be employed without limitation. Non-limiting examples include materials formed of or containing one or more of Cr, Ti, Al, Au, Ni, ZnO, AZO, ITO, and oxides or alloys thereof, alone or in combination. When the selective alignment layer is the electrode layer 40, its thickness may be 10 to 500 nm, but is not limited thereto. The selective alignment suppression layer 60 may be made of a material having a lower electrical conductivity than the second conductive semiconductor layer 30 or the electrode layer 40. The selective alignment suppression layer 60 may be, for example, an electron blocking layer having an electron delay function, which prevents electrons and holes from recombining outside the light-active layer 20 due to a difference in mobility when the LED device 103 has a reduced thickness. Non-limiting examples of the electron blocking layer include one or more of CdS, GaS, ZnS, CdSe, CaSe, ZnSe, CdTe, GaTe, SiC, ZnO, ZnMgO, SnO₂, TiO₂, In₂O₃, Ga₂O₃, Si, poly(paraphenylene vinylene) its and derivatives, polyaniline, poly(3-alkylthiophene), and poly(paraphenylene). Alternatively, when the first conductive semiconductor layer 10 is an n-type III-nitride semiconductor layer, the electron blocking layer may be formed of a Ill-nitride semiconductor having a doping concentration lower than that of the first conductive semiconductor layer 10. The thickness of the selective alignment suppression layer 60 may be 1 to 100 nm, but is not limited thereto.

In addition, during self-alignment using dielectrophoretic force, the sidewalls of the LED devices 101, 102, 103 may include a first rotation-inducing film in place of the protective film 80, so that a specific one of the first and second surfaces of the LED devices 101, 102, 103 becomes a mounting surface contacting the upper surfaces of the lower electrodes 201, 202. The first rotation-inducing film may generate a rotational torque about an imaginary rotation axis passing through the center of the LED device in the longitudinal direction of the device. The material of the first rotation-inducing film may be appropriately selected in consideration of the dielectric constant of the solvent and the frequency range of the power applied for self-alignment.

In addition, during self-alignment using dielectrophoretic force, an assembly power supply may be applied between adjacent lower electrodes 201, 202, preferably having a frequency of 1 kHz to 100 MHz and a voltage of 5 to 100 Vpp. More preferably, the assembly power supply may have a frequency of 1 kHz to 200 kHz and a voltage of 10 to 80 Vpp.

Alternatively, as shown in FIG. 8, to be more suitable for electro-osmotic pressure, an LED device 104 may have a ratio (n/m) of the thickness (n) in the stacking direction of the layers 10, 20, 30, 40 to the major-axis length (m) in a cross-section perpendicular to the stacking direction greater than 0 and less than or equal to 2.0. The LED device 104 may include a second rotation-inducing film on its sidewall in place of the protective film 80, thereby causing a difference in physical properties between the sidewall and the upper and lower surfaces of the LED device 104. The difference in physical properties between the sidewall and the upper/lower surfaces due to the material difference may generate a rotational torque in the LED device 104 about an axis perpendicular to the stacking direction of the layers under an electric field. Accordingly, the LED device 104 having the second rotation-inducing film on its sidewall may rotate about an axis perpendicular to the stacking direction after being moved onto the upper surface of the lower electrodes 211, 212, 213 by electro-osmotic pressure, thereby increasing the mounting ratio in which the upper or lower surface, rather than the sidewall, contacts the upper surface of the lower electrode. The second rotation-inducing film configured to facilitate self-alignment by electro-osmotic pressure may have a dielectric constant (E) of 30 or less, preferably 7 or less, more preferably 5.5 or less, and in another example, 3.0 or greater. Through such dielectric properties, it is possible to increase both the ratio (or number) of LED devices moved and seated on the upper surface of the lower electrode and the mounting ratio of operable LED devices. The second rotation-inducing film may be formed of any material that provides a difference in physical properties from the upper/lower surfaces of the LED device 104, and preferably of a material satisfying the above dielectric-constant conditions. By way of example, the second rotation-inducing film may be made of one or more materials selected from HfO₂, ZrO₂, Al₂O₃, SiO₂, and SiNx; in another example, one or more of Al₂O₃, SiO₂, and SiNx; and in yet another example, one or more of SiO₂ and SiNx.

In addition, by way of example, during self-alignment based on electro-osmotic pressure, a power supply having a frequency of 500 Hz or less may be applied to the lower electrodes 211, 212 so that the dominant force acting on the LED device 104 positioned within the electric field formed between the two adjacent lower electrodes 211, 212 becomes the electro-osmotic pressure. Preferably, the power applied to the lower electrodes 211, 212 may have a frequency of 1 to 500 Hz and a voltage of 5 to 100 Vpp; more preferably, a frequency of 1 to 50 Hz and a voltage of 5 to 80 Vpp; even more preferably, a frequency of 1 to 30 Hz and a voltage of 5 to 50 Vpp; and most preferably, a frequency of 5 to 20 Hz and a voltage of 5 to 40 Vpp. Through such conditions, the LED devices can be effectively moved and aligned onto the upper surfaces of the lower electrodes with high efficiency, while preventing or minimizing damage to the lower electrodes.

Alternatively, the LED device may be mounted onto the lower electrode by sedimentation under gravity while being dispersed in a solvent. In this case, the LED device may satisfy a ratio of 1:0.5-1.5, preferably 1:0.8-1.2, and more preferably 1:0.9-1.1 between the thickness in the stacking direction of the layers constituting the device and the length of the major axis on an end surface perpendicular to the stacking direction—for example, the upper and/or lower surface of the LED device. Such a dimensional ratio enables the LED device to exhibit excellent dispersibility in the solvent and maintain a stable dispersion state without rapid sedimentation over time. To further improve dispersion stability—namely, the ability of the LED device to remain suspended without settling during ink formulation—the LED device may have a maximum planar area of 16 μm² or less, preferably 9 μm² or less, more preferably 4 μm² or less, and most preferably 0.1-2.5 μm². Here, the “maximum planar area” refers to the largest projected area of the LED device when viewed from any direction. If the maximum planar area exceeds 16 μm², the sedimentation rate may increase, reducing dispersion stability, and the device may become unsuitable for ink formulation unless additional dispersants or special solvents are used. In addition, in self-alignment using gravitational sedimentation, to ensure that the LED device is effectively guided onto the upper surface of the lower electrode and that either the first or the second surface becomes the mounting surface, one surface of the LED device in the thickness direction may further include a selective bonding layer. The selective bonding layer may be, for example, a magnetic layer. Alternatively, the selective bonding layer may be a chemical bonding layer. When the LED device includes a chemical bonding layer, the chemical bonding layer may be a first charge layer having a positive or negative charge capable of ionic bonding, or a covalent-bond-inducing layer having a first functional group capable of covalent bonding. In this case, the upper surface of the lower electrode may be modified to include an opposite charge to the first charge layer, or to include a known second functional group capable of forming a covalent bond with the first functional group of the selective bonding layer.

Next, as step (3) of the present disclosure, a step of forming an upper electrode line 300 on the plurality of self-aligned LED devices 101, 102, 103, 104 is performed.

The upper electrode line 300 is not limited in number, arrangement, or shape, as long as it is designed to be in electrical contact with upper portions of the LED devices disposed on the lower electrode line 200, 200′. The upper electrode line 300 may be formed, for example, by patterning the electrode line through a known photolithography process followed by deposition of an electrode material, or by depositing an electrode material and then performing dry and/or wet-etching. Detailed descriptions of the specific formation methods are omitted hereinafter.

In addition, before forming the upper electrode line 300, a step of forming a conduction metal layer 500 and/or a passivation layer 600 on the lower electrode line 200, 200′ on which the LED devices 101, 102, 103, 104 are arranged may be further included.

The conduction metal layer 500 may be fabricated by patterning lines for the conduction metal layer using a photolithography process employing a photosensitive material, followed by deposition of the conduction metal layer, or alternatively by depositing the metal layer first and then patterning and etching it. Such processes may be appropriately performed using known methods, and Korean Patent Application No. 10-2016-0181410 filed by the inventor of the present disclosure is incorporated herein by reference.

After forming the conduction metal layer 500, a passivation layer 600 may be formed on the self-aligned LED devices 101, 104. The passivation layer 600 may be made of any passivation material commonly used in electronic and electrical components without limitation. For example, the passivation layer 600 may be deposited by a PECVD process using passivation materials such as SiO₂ or SiNₓ, by an MOCVD process using materials such as AlN or GaN, or by an ALD process using materials such as Al₂O₃, HfO₂, or ZrO₂. The passivation layer 600 should be formed such that it does not cover the upper surfaces of the self-aligned LED devices 101 and 104. To achieve this, the passivation layer may be deposited to a thickness that does not cover the upper surfaces, or alternatively, it may first be deposited to cover the upper surfaces and then dry-etched to expose the upper surfaces of the LED devices.

Meanwhile, in the full-color LED display 1000, 1000′ according to the first embodiment, after step (3), step (4) may be further performed. In step (4), a color conversion layer 700 is patterned on the upper electrode line 300 such that, among the plurality of sub-pixel regions S₁, S₂, S₃, some sub-pixel regions emit at least two colors different from the first color. For example, when the first color is UV, the corresponding sub-pixel regions may emit blue, green, and red; alternatively, when the first color is blue, the corresponding sub-pixel regions may emit green and red.

Specifically, the color conversion layer 700 may be formed by patterning a green color conversion layer 711 on some of the sub-pixel regions selected to have green chromaticity, patterning a red color conversion layer 712 on other sub-pixel regions selected to have red chromaticity, and patterning a blue color conversion layer 713 on the remaining sub-pixel regions selected to have blue chromaticity. The patterning may be performed by one or more methods selected from the group consisting of screen printing, photolithography, and dispensing. Meanwhile, the sequence of patterning the green color conversion layer 711, red color conversion layer 712, and blue color conversion layer 713 is not limited, and they may be formed simultaneously or in reverse order. In addition, the red color conversion layer 712, green color conversion layer 711, and blue color conversion layer 713 may employ any known color conversion materials used in the display field, such as color filters, phosphors, or quantum dots that can be excited by UV LED devices and convert light into desired chromatic colors. The present disclosure is not particularly limited thereto.

The full-color LED displays 1000, 1000′, 2000, 2000′ manufactured by the above-described production method may include, in each independently drivable sub-pixel region, for example, 1 to 100,000 LED devices 101, 102, 103, 104, although the present disclosure is not limited thereto.

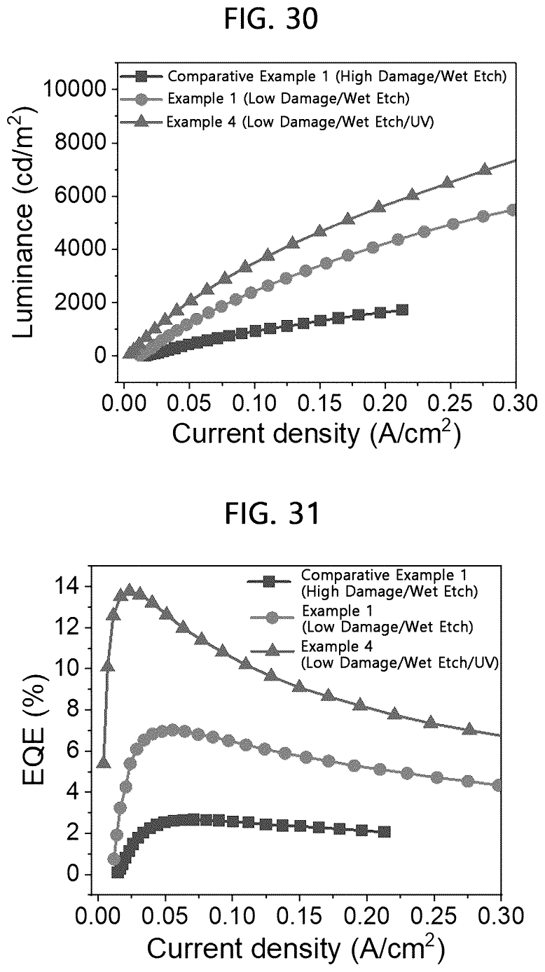

In addition, according to an embodiment of the present disclosure, the full-color display thus implemented may exhibit an excellent luminance of 2000 cd/m² or higher at a current density of 110 mA/m² (see FIG. 30). Furthermore, the LED devices 101 provided in the full-color display may have a maximum external quantum efficiency ranging from 5% to 20%. For example, referring to FIG. 31, values of 7.02% and 13.76% can be observed.

### EXAMPLES

The following examples are provided to describe the present disclosure in further detail; however, these examples are not intended to limit the scope of the present disclosure and should be construed merely to facilitate understanding thereof.

To evaluate the characteristics of LED devices employed in the full-color LED display, experiments were carried out as described below.

### Example 1

### Preparation Example 1

A conventional LED wafer (Epistar) was prepared, in which an undoped n-type III-nitride semiconductor layer, a Si-doped n-type III-nitride semiconductor layer (thickness: 4 μm), a light-active layer (thickness: 0.15 μm), and a p-type III-nitride semiconductor layer (thickness: 0.05 μm) were sequentially stacked on a substrate. On the prepared LED wafer, an electrode layer of indium-tin oxide (ITO; thickness: 0.15 μm), a first mask layer of SiO₂ (thickness: 1.2 μm), and a second mask layer of Ni (thickness: 80.6 nm) were sequentially deposited. Subsequently, a spin-on-glass (SOG) resin layer having a rectangular pattern was transferred onto the second mask layer using a nanoimprint apparatus. The SOG resin layer was then hardened under RIE plasma, and residual resin portions were removed by RIE to form a resin pattern layer. Following the pattern, the second mask layer was etched using inductively coupled plasma (ICP), and the first mask layer was etched using RIE. Thereafter, the first electrode layer, the p-type Ill-nitride semiconductor layer, and the light-active layer were dry-etched using ICP-RIE under the process-gas composition, process pressure, ICP power, RF power, DC-bias voltage, and etching rate conditions listed in TABLE 1. Subsequently, the doped n-type III-nitride semiconductor layer was further dry-etched to a thickness of 0.5 μm to form a plurality of spaced-apart structures. At this time, the included angle between the etched side surface and the bottom surface of each structure was measured to be 80°.

### Preparation Example 2

The wafer having a plurality of structures formed therein, which was prepared in Preparation Example 1, was subjected to a first recovery step of wet-etching by immersing the wafer in an ammonium salt etching solution containing hydroxyl groups for 13 minutes. Through this wet-etching process, a wafer was obtained in which a plurality of structures (long axis: 4 μm, short axis: 700 nm, height: 950 nm) were formed with the mask pattern layer removed.

### Example 2

The procedure was carried out in the same manner as in Example 1, except that the dry-etching conditions using ICP-RIE were changed as shown in TABLE 1, thereby producing a wafer in which a plurality of structures were formed. According to the modified dry-etching conditions, the included angle between the etched side surface of each structure and the bottom surface of the structure after dry-etching was 83°.

### Example 3

The procedure was carried out in the same manner as in Example 1, except that the dry-etching conditions using ICP-RIE were changed as shown in TABLE 1, thereby producing a wafer in which a plurality of structures were formed. According to the modified dry-etching conditions, the included angle between the etched side surface of each structure and the bottom surface of the structure after dry-etching was 82°.

### Comparative Example 1

### Comparative Preparation Example 1

The procedure was carried out in the same manner as in Preparation Example 1 of Example 1, except that the dry-etching conditions using ICP-RIE were changed as shown in TABLE 1. According to the modified dry-etching conditions, the included angle between the etched sidewall of each structure and the bottom surface of the structure after dry-etching was 88°.

### Comparative Preparation Example 2

The wafer having a plurality of structures formed therein, which was prepared in Comparative Preparation Example 1, was subjected to the same wet-etching procedure as described in Preparation Example 2 of Example 1, thereby producing a wafer in which a plurality of structures were formed.

### Example 4

The procedure was carried out in the same manner as in Example 1, except that after performing the dry-etching and the first recovery step of wet-etching, a second recovery step was additionally performed by irradiating UV light having a wavelength of 265 nm at an intensity of 3.3 mW for 24 hours, thereby producing a wafer in which a plurality of structures were formed.

### Comparative Example 2

The procedure was carried out in the same manner as in Comparative Example 1, except that after performing the dry-etching and the first recovery step of wet-etching in Comparative Preparation Examples 1 and 2, a second recovery step was additionally performed by irradiating UV light having a wavelength of 265 nm at an intensity of 3.3 mW for 24 hours, thereby producing a wafer in which a plurality of structures were formed.

### Manufacturing Example 1

To separate a plurality of structures from the prepared wafer in which the structures were formed, a separation method disclosed in Korean Patent Laid-Open Publication No. 2022-0096608, proposed by the present inventors, was employed. Specifically, a temporary protective film of Al₂O₃ was deposited on the wafer on which the structures were formed (with a deposition thickness of 72 nm, measured based on the sidewall of the structures). Subsequently, the temporary protective film material formed between the plurality of structures was removed by reactive ion etching (RIE) to expose the upper surface of the doped n-type III-nitride semiconductor layer located between the structures.

The LED wafer having a temporary protective film formed thereon was immersed in an electrolytic solution of 0.3 M oxalic acid and connected to the anode terminal of a power supply, while a platinum electrode immersed in the same electrolytic solution was connected to the cathode terminal. A voltage of 15 V was applied for 5 minutes, thereby forming a plurality of pores in the doped n-type III-nitride semiconductor layer between the structures from the surface thereof in the thickness direction. After the electrochemical pore formation, the temporary protective film was removed using inductively coupled plasma (ICP), and a SiO₂ protective film was deposited to a thickness of 60 nm (measured based on the sidewall of the LED structures). Subsequently, the rotational-alignment-inducing film material formed between the LED structures was removed by reactive ion etching (RIE) to expose the upper surface of the doped n-type III-nitride semiconductor layer between the structures. Thereafter, the wafer was immersed in a bubble-forming solution composed of 100% γ-butyrolactone, and ultrasonic waves were applied at 160 W and 40 kHz for 10 minutes. By utilizing the generated bubbles, the pores formed in the doped n-type III-nitride semiconductor layer were collapsed, thereby separating a plurality of LED devices from the wafer.

TABLE 1

| | | Comparative |
|---|---|---|
| ICP-RIE Conditions Item | Example 1 | Example 1 |
| Process Gas (Flow Rate, | Cl₂(10), BCl₃ (10) | Cl₂(10), BCl₃ (10) |
| sccm) | | |
| Process Pressure (mTorr) | 7.5 | 7.5 |
| ICP Power (W) | 125 | 500 |
| RF Power (W) | 25 | 200 |
| DC Bias Voltage (V) | 170 | 660 |
| Etching Rate (nm/min) | 36 | 250 |
| Included Angle Between LED | 80 | 88 |
| Structure and Wafer (°) | | |
| ICP-RIE Conditions Item | Example 2 | Example 3 |
| Process Gas (Flow Rate, | Cl₂(10), BCl₃ (10) | Cl₂(10), BCl₃ (10) |
| sccm) | | |
| Process Pressure (mTorr) | 7.5 | 7.5 |
| ICP Power (W) | 350 | 200 |
| RF Power (W) | 100 | 50 |
| DC Bias Voltage (V) | 170 | 170 |
| Etching Rate (nm/min) | 150 | 100 |
| Included Angle Between LED | 83 | 82 |
| Structure and Wafer (°) | | |

### Experimental Example 1

The physical properties of the wafers having a plurality of structures formed therein, which were prepared according to Examples 1 to 4 and Comparative Examples 1 and 2, were measured as follows.

### 1. SEM Observation

SEM images were taken for the structures formed on the wafers obtained through Preparatory Example 1 and Example 1, and through Comparative Preparatory Example 1 and Comparative Example 1, respectively. The results are shown in FIG. 13A (left—Preparatory Example 1, right—Example 1) and FIG. 13B (left—Comparative Preparatory Example 1, right—Comparative Example 1).

As can be seen from FIGS. 13A and 13B, when the dry-etching performed through inductively coupled plasma-reactive ion etching (ICP-RIE) proceeds predominantly by physical etching rather than chemical etching, the etched plane is formed almost vertically—at approximately 88° with respect to the main surface of the wafer—as shown in the schematic view and image on the left of FIG. 13B. In contrast, when the dry-etching performed through ICP-RIE proceeds predominantly by chemical etching rather than physical etching, the etched plane is inclined in a tapered shape, as illustrated in the schematic view and image on the left of FIG. 13A.

On the other hand, after the wet-etching, it can be observed that the etched plane becomes substantially perpendicular to the main surface of the wafer, as illustrated in the schematic views and images on the right sides of FIGS. 13A and 13B.

### 2. TEM Observation and Analysis

TEM images were taken for the sidewalls (etched planes) of individual structures formed on the wafers prepared according to Preparatory Example 1 based on Example 1 and Comparative Preparatory Example 1 based on Comparative Example 1. The results are shown in FIG. 14 (Preparatory Example 1) and FIG. 15 (Comparative Preparatory Example 1).

As can be seen from FIGS. 14 and 15, both the structure etched through the limited high-damage dry-etching in Comparative Preparatory Example 1 and the structure etched through the recoverable low-damage dry-etching in Preparatory Example 1 maintain almost the same crystalline structure, as confirmed from the diffraction patterns (see the upper-right insets in each figure).

However, when the high-resolution TEM images are examined, the structure subjected to the limited high-damage dry-etching in Comparative Preparatory Example 1 exhibits a larger dark-spot region—that is, a dead volume corresponding to surface and internal defects—than that of the structure subjected to the recoverable low-damage dry-etching in Preparatory Example 1. Accordingly, it can be inferred that the limited high-damage dry-etching produces a greater number of surface defects compared to the recoverable low-damage dry-etching.

### 3. Raman Spectroscopy and XPS Analysis

Raman spectra as a function of wavelength were obtained for the same wafer used in Example 1 and for the wafers having a plurality of structures formed according to Preparatory Example 1, Example 1, Example 4, Comparative Preparatory Example 1, Comparative Example 1, and Comparative Example 2. The results are shown in FIG. 16. Additionally, FIG. 17 shows the spectra of the Ga 3d binding peaks obtained from X-ray photoelectron spectroscopy (XPS) analysis. Using the results of FIG. 17, the Ga 3d spectra were deconvoluted into Ga—O, Ga—Ga, and Ga—N components, and their relative quantities were quantified by fitting the peaks with a Gaussian function. The quantitative results are presented in FIG. 18.

As can be seen from FIG. 16, the Comparative Preparatory Example 1, in which limited high-damage dry-etching was performed, exhibits a defect peak around a wavenumber of 687 cm⁻¹, corresponding to a Ga-vacancy defect. Similarly, the Preparatory Example 1, in which recoverable low-damage dry-etching was performed, also shows a Ga-vacancy-related defect peak, although the intensity is considerably smaller.

In addition, Comparative Example 1, which underwent the first recovery step (wet-etching) after the limited high-damage dry-etching, exhibited a ratio of 11% between the peak area of the Ga-vacancy-related defect mode at 687 cm⁻¹ and the peak area of the GaN A₁(LO) mode at 746.62 cm⁻¹. In contrast, in Example 1, which underwent the first recovery step (wet-etching) after the recoverable low-damage dry-etching, the ratio of the peak area of the Ga-vacancy-related defect mode was reduced to about 4.8%, indicating that the amount of Ga-vacancy defects remaining on the sidewall of the LED device after recovery was significantly reduced. Accordingly, it can be confirmed that an LED device having superior light-emission efficiency can be obtained as a result.

Furthermore, Comparative Example 2, which underwent the limited high-damage dry-etching, the first recovery step (wet-etching), and the second recovery step (UV irradiation), exhibited a defect peak around a wavenumber of 687 cm⁻¹, corresponding to a Ga-vacancy defect. In contrast, Example 4, which underwent the recoverable low-damage dry-etching, the first recovery step, and the second recovery step, showed only a very weak Ga-vacancy-related defect peak, confirming that the defects were substantially recovered.

Furthermore, as can be seen from FIGS. 17 and 18, the structure according to Comparative Preparatory Example 1, which was fabricated through limited high-damage dry-etching, showed that the proportion of Ga—O bonds increased from 11% in the wafer itself to 21%, corresponding to an increase of about 90%, and the proportion of Ga—Ga bonds increased from 9% to 23%, corresponding to an increase of about 156%. In contrast, the structure according to Preparatory Example 1, fabricated through recoverable low-damage dry-etching, exhibited a decrease in Ga—O bonds from 11% to 10% (about 9.1% reduction) and an increase in Ga—Ga bonds from 9% to 20% (about 122% increase). Accordingly, it can be confirmed that, compared to Comparative Preparatory Example 1, the Ga—O bond concentration decreased, while the Ga—Ga bond increase was less pronounced.

In addition, Example 1, which underwent the first recovery step (wet-etching) after recoverable low-damage dry-etching, showed that the Ga—O bonds generated by the dry-etching were substantially reduced and recovered to 9%, which is even lower than the 11% Ga—O bond ratio inherent in the wafer before dry-etching. The Ga—Ga bonds were also recovered to 12%, slightly higher than the 9% ratio of the wafer itself. In contrast, Comparative Example 1, which underwent the first recovery step after limited high-damage dry-etching, exhibited a Ga—Ga bond ratio of 23%, indicating that the Ga—Ga bonds generated during dry-etching were not removed even after the first recovery step, and thus significantly increased compared with the 9% ratio of the wafer itself. Furthermore, in Comparative Example 1, although the Ga—O bond ratio decreased from 21% to 16% after the first recovery step, it still remained higher than the 11% Ga—O bond ratio inherent in the wafer, confirming that recovery was only marginal compared with Example 1.

Furthermore, Comparative Example 2, which underwent the first recovery step (wet-etching) followed by the second recovery step (UV irradiation) after the limited high-damage dry-etching, showed that the Ga—O bond ratio increased to 19%, which is about 72.7% higher than the 11% Ga—O bond ratio inherent in the wafer, even after both recovery steps. Specifically, although the Ga—O bond ratio initially decreased from 21% to 16% after the first recovery step, it increased again to 19% after the second recovery step, confirming that the Ga—O bonds were not recovered but rather increased by the UV irradiation process.

In addition, Comparative Example 2, even after undergoing both the first recovery step and the second recovery step, exhibited a Ga—Ga bond ratio that increased from 9% in the wafer itself to 21%, corresponding to an increase of approximately 133.3%. Since the Ga—Ga bond ratio after the first recovery step remained the same as that immediately after dry-etching (23%), it can be understood that the first recovery step in Comparative Example 2 either failed to recover the Ga—Ga bonds or achieved only negligible recovery.

In contrast, Example 4, in which the structure produced by the recoverable low-damage dry-etching of Preparation Example 1 underwent both the first recovery step and the second recovery step, exhibited a Ga—O bond ratio of 10%, which is lower than the 11% ratio inherent in the wafer itself. This result confirms that the Ga—O bond defects were recovered to the same level as, or even better than, the pre-etching wafer state. In addition, Example 4 showed a Ga—Ga bond ratio of 11%, which represents only a slight increase (about 22%) compared with the 9% ratio of the wafer, indicating that the Ga—Ga bond defects were also recovered to a level close to that before dry-etching. The recovery level of the Ga—Ga bond defects in Example 4 can therefore be regarded as remarkably superior to that of Comparative Example 2.

### 4. Evaluation of Photoluminescence (PL) and Internal Quantum Efficiency (IQE) by Temperature

Photoluminescence (PL) was measured at 300 K and 10 K for the wafers used in Example 1, as well as for the wafers obtained according to Preparation Example 1, Examples 1 and 4, Comparative Preparation Example 1, and Comparative Examples 1 and 2, each having a plurality of structures formed thereon. The results are shown in FIGS. 19 and 20, respectively.

In addition, the internal quantum efficiency was calculated using the changes in PL intensity measured at different temperatures according to Equation 1 below, and the results are presented in FIG. 21.

$${η}_{IQE} = IPL ( 300 K ) IPL ( 10 K ) \qquad [ Equation 1 ]$$

where IPL (A) represents the integrated PL intensity measured at an absolute temperature A (K).

As can be seen from FIGS. 19 to 21, at a low temperature of 10 K (see FIG. 20), the PL intensities of the examples and comparative examples are almost identical regardless of the etching method. This is interpreted as follows: when the temperature decreases, electrons excited at surface defects are not trapped, and thus yellow emission caused by the defects and nonradiative recombination are quenched and nearly disappear. Consequently, excitons between the conduction band and the valence band predominantly participate in radiative recombination, resulting in enhanced blue emission and similar PL intensities among most samples.

However, as shown in FIG. 19, when PL is measured at room temperature (300 K), the comparative preparation example 1 subjected to the limited high-damage dry-etching exhibits a large number of surface defects generated after dry-etching. Even though the amorphous surface structure is removed by wet-etching (comparative example 1), a substantial amount of surface defects still remains, so that the blue emission partially recovers but does not increase to the desired level. In contrast, in Examples 1 and 2, the blue emission intensity is significantly recovered due to the reduction and healing of surface defects formed by the dry-etching.

Meanwhile, as shown in FIG. 21, the internal quantum efficiency (IQE) of the comparative preparation example 1 subjected to the limited high-damage dry-etching is about 1.48%. After undergoing the subsequent wet-etching first recovery step, the comparative example 1 reaches an IQE of 14.0%, representing about a ten-fold increase compared with the comparative preparation example 1; however, the absolute value still remains low. In contrast, in the recoverable low-damage dry-etched preparation example 1, the IQE already reaches 40.4% even before the first recovery step, and the example 1 that has undergone the wet-etching first recovery step achieves an IQE as high as 54.8%. Accordingly, the recoverable low-damage dry-etching alone results in only a small reduction in IQE, and the IQE of example 1 is about 3.9 times higher than that of comparative example 1.

### 5. Evaluation of Average Decay Time 1

Time-correlated single photon counting (TCSPC) was performed to measure the average decay time for the wafers used in Example 1 and for the wafers having a plurality of structures formed thereon according to Preparation Example 1, Example 1, Comparative Preparation Example 1, and Comparative Example 1. The results are shown in FIG. 22.

As can be seen from FIG. 22, the PL decay time of the recoverable low-damage dry-etched sample of Preparation Example 1 was 106.9 ns after dry-etching, and that of the subsequent wet-etched first-recovery-step sample of Example 1 increased to 204.3 ns.

In contrast, the PL decay time of the limited high-damage dry-etched Comparative Preparation Example 1 was 3.1 ns after dry-etching, and that of Comparative Example 1, which underwent the wet-etching first-recovery step, increased to 25.4 ns. Nevertheless, these values remain much shorter than those of Preparation Example 1 and Example 1.

### 6. PL Emission Characteristics and Internal Quantum Efficiency According to UV Irradiation Time

PL emission was measured for wafers having a plurality of structures formed thereon, which were obtained by varying the UV irradiation time in the second recovery step in Example 4 and Comparative Example 2. The results are shown in FIG. 24 (Example 4) and FIG. 25 (Comparative Example 2).

In addition, photoluminescence (PL) was measured at 300 K and 10 K, and the internal quantum efficiency (IQE) was calculated using the temperature-dependent PL variation according to Equation 1 described above. The results are presented in FIG. 26.

As can be seen from FIGS. 24 and 25, Example 4, which underwent the first recovery step of wet-etching after recoverable low-damage dry-etching and the subsequent second recovery step of UV irradiation, shows a consistent increase in the PL peak intensity with UV irradiation time, indicating that the defects are passivated by moisture.

In contrast, Comparative Example 2, which underwent the first recovery step of wet-etching after limited high-damage dry-etching and the subsequent second recovery step of UV irradiation, exhibits almost no change in emission characteristics even after the UV irradiation.

### 7. Evaluation of Average Decay Time 2

The average decay time was measured for Example 4 and Comparative Example 2 in the same manner as in Experimental Example 1, and the results are shown in FIG. 27 (Example 4) and FIG. 28 (Comparative Example 2). In this case, the LED devices according to Example 4 and Comparative Example 2 were those irradiated with UV for 24 hours.

As shown in FIGS. 27 and 28, the LED device of Example 4, which underwent the recoverable low-damage dry-etching, the first recovery step of wet-etching, and the second recovery step of UV irradiation, exhibited a longer decay time at room temperature (300 K) than at low temperature (10 K). This indicates that the photoluminescence decay slows down as the temperature increases, implying effective passivation of residual defects and dangling bonds. In contrast, the LED device of Comparative Example 2, which underwent the limited high-damage dry-etching, the first recovery step of wet-etching, and the second recovery step of UV irradiation, showed the opposite trend: the decay time became shorter as the temperature increased from 10 K to 300 K, which is consistent with the emission mechanism of luminescent materials containing a high density of defects.

### Manufacturing Example 2

LED devices were obtained by separating a plurality of structures from the wafers having a plurality of structures formed thereon according to Examples 1 and 4 and Comparative Example 1, in accordance with Manufacturing Example 1 described above. Thereafter, full-color displays were fabricated from the obtained LED devices by the following method as illustrated in FIG. 2. In this case, the LED devices according to Example 4 were those irradiated with UV for 24 hours.

Specifically, a lower electrode line was fabricated on a base substrate made of quartz having a thickness of 500 μm, such that a plurality of lower electrodes elongated in a first direction were spaced apart from each other by 3 μm in a second direction perpendicular to the first direction. Each of the lower electrodes had a width of 10 μm and a thickness of 0.2 μm, and was made of gold (Au). In addition, the area of a sub-pixel region in which the LED device is mounted on the lower electrode line was set to 1 mm². Furthermore, an insulating partition wall made of SiO₂ having a height of 0.5 μm was formed on the base substrate to surround the sub-pixel region in which the LED device is mounted.

Subsequently, a dispersion was prepared by mixing the prepared LED devices in acetone having a dielectric constant of 20.7. Thereafter, 9 μL of the prepared dispersion was dropped twice onto each sub-pixel region, and an alternating current (AC) assembly voltage having a sine waveform of 10 KHz and 40 Vpp was applied between two adjacent lower electrodes to mount the LED devices on the lower electrode line through dielectrophoresis.

Subsequently, a passivation material of SiO₂ was deposited to a thickness of 100 nm on the sub-pixel regions on which the LED devices were mounted by a PECVD process. Thereafter, a polymer material such as SU-8 was coated to a height corresponding to the thickness of the LED devices. Then, a plurality of upper electrodes (having a width of 10 μm, a thickness of 0.2 μm, an interval of 3 μm between adjacent electrodes, and made of gold) extending in a second direction perpendicular to the first direction and spaced apart from each other in the first direction were formed on the upper surfaces of the mounted LED devices. Afterward, color conversion layers were patterned on the upper electrode lines corresponding to the respective sub-pixel regions so that each sub-pixel region exhibited one of blue, green, and red colors, thereby fabricating a color-by-blue type full-color LED display.

### Experimental Example 2

The full-color LED display fabricated according to Manufacturing Example 2 was driven by applying a driving power supply to the lower and upper electrodes while varying the current density. The luminance of the emitted light was then measured, and the results for the blue LED device are illustrated in FIG. 30. In addition, based on the results shown in FIGS. 19 and 20, the external quantum efficiency (EQE) was calculated, and the results are presented in FIG. 31.

As can be seen from FIGS. 30 and 31, the maximum external quantum efficiency (EQE) of the blue LED display including the LED devices according to Comparative Example 1 is only 2.65%, whereas the blue LED display including the LED devices according to Example 1 exhibits a maximum external quantum efficiency of 7.02%. Further, the blue LED display including the LED devices according to Example 2 achieves an external quantum efficiency as high as 13.76%. Accordingly, it can be confirmed that the overall efficiency of the full-color display based on these LED devices is significantly improved.

In addition, the blue LED display including the LED devices according to Comparative Example 1 exhibited a luminance of 1,024 cd/m² at a current density of 112 mA/m². In contrast, the blue LED display including the LED devices according to Example 1 achieved a luminance of 2,637 cd/m² at a current density of 110 mA/m², and the blue LED display including the LED devices according to Example 4 reached a luminance of 3,747 cd/m² at a current density of 110 mA/m².

Accordingly, these results demonstrate that the LED devices having defects and dangling bonds on the etched surfaces recovered through Example 4 exhibit excellent luminous efficiency. By employing such LED devices to realize blue color emission, the full-color LED display can achieve remarkably improved external quantum efficiency and luminance performance.

Although an embodiment of the present disclosure has been described above, the spirit of the present disclosure is not limited to the embodiments presented in this specification, and those skilled in the art who understand the spirit of the present disclosure can easily propose other embodiments within the same spirit by addition, modification, deletion, or supplementation of components, which are also considered within the scope of the present disclosure.

What is claimed is:

1. A method of manufacturing a full-color LED display, comprising:
(1) dispensing, onto a lower electrode line having a plurality of sub-pixel regions formed thereon, a solution containing LED devices, each LED device having a first surface and a second surface opposite to each other in a thickness direction in which a plurality of layers are stacked, and having remaining sidewalls, a thickness of each LED device being 10 μm or less, an area of a cross-section perpendicular to the thickness direction being 100 μm² or less, and an average decay time measured at 300 K being equal to or longer than an average decay time measured at 10 K;
(2) self-aligning each LED device introduced into each sub-pixel region on the lower electrode line such that either the first surface or the second surface of each LED device becomes a mounting surface; and
(3) forming an upper electrode line on the self-aligned LED devices.

2. The method of claim 1, wherein the LED device emits a first color, and further comprising, after step (3):
(4) patterning a color conversion layer on the upper electrode line such that at least two of the sub-pixel regions among the plurality of sub-pixel regions emit colors different from the first color.

3. The method of claim 1, wherein, in step (1), the solution containing the LED devices comprises three solutions respectively containing blue LED devices, green LED devices, and red LED devices, which are dispensed onto the lower electrode line such that each sub-pixel region emits a respective chromatic color.

4. The method of claim 1, wherein the LED devices are manufactured by:
dry-etching a wafer downward from an upper surface along a predefined pattern to form a plurality of structures spaced apart from each other between their sidewalls, the dry-etching being performed such that an included angle between a dry-etched sidewall of each structure and a dry-etched bottom surface of the structure continuous with the wafer is 60° to 84°; and
wet-etching the structures produced by the dry-etching to remove surface defects on the dry-etched sidewall of each structure, which is defined as a first recovery step.

5. The method of claim 4, wherein the dry-etching is performed by inductively coupled plasma-reactive ion etching (ICP-RIE) at an etching rate of 200 nm/min or less.

6. The method of claim 4, wherein the first recovery step is performed such that an included angle between a wet-etched sidewall of each structure and a wet-etched bottom surface of the structure continuous with the wafer is 85° or more.

7. The method of claim 4, wherein each structure includes a first conductive semiconductor layer of a gallium nitride (GaN)-based semiconductor, a light-active layer, and a second conductive semiconductor layer,
wherein a sidewall of the LED structure subjected to the first recovery step exhibits, in Ga 3d bond analysis by XPS, a change in the ratio of Ga—O bonds—which represent defects among Ga—N and Ga—O bonds—of less than +30% relative to the Ga—O bond ratio of the wafer itself.

8. The method of claim 4, wherein the LED structure prior to the first recovery step after the dry-etching exhibits, in Raman spectral analysis, a ratio of the peak area of a Ga-vacancy-related defect mode located around 687 cm 1 to the peak area of a GaN A₁(LO) mode located around 746.62 cm⁻¹ of 15% or less.

9. The method of claim 4, wherein the LED structure subjected to the first recovery step exhibits, in Raman spectral analysis, a ratio of the peak area of a Ga-vacancy-related defect mode located around 687 cm⁻¹ to the peak area of a GaN A₁(LO) mode located around 746.62 cm⁻¹ of 8% or less.

10. The method of claim 4, further comprising, after the first recovery step:
irradiating the LED structure with UV, which is defined as a second recovery step.

11. The method of claim 10, wherein the second recovery step includes irradiating UV having a wavelength of 250 to 400 nm at a power of 1 mW to 100 W for 0.1 to 48 hours.

12. A full-color LED display comprising a plurality of sub-pixel regions,
each sub-pixel region including:
a lower electrode line;
at least one LED device having a first surface and a second surface opposite to each other in a thickness direction in which a plurality of layers are stacked and remaining sidewalls, either the first surface or second surface of each LED device being mounted to contact the lower electrode line in each sub-pixel region, a thickness of each LED device being 10 μm or less, an area of a cross-section perpendicular to the thickness direction being 100 μm² or less, and an average decay time measured at 300 K being equal to or longer than an average decay time measured at 10 K;
an upper electrode line disposed on the LED device.

13. The full-color LED display of claim 12, wherein each sub-pixel region includes an LED device emitting a first color,
the display further comprising:
a color conversion layer provided on the upper electrode line corresponding to each of the plurality of sub-pixel regions, so that each sub-pixel region emits one of blue, green, and red colors.

14. The full-color LED display of claim 12, wherein the plurality of sub-pixel regions includes a blue sub-pixel region, a green sub-pixel region, and a red sub-pixel region, each sub-pixel region having an LED device emitting a corresponding chromatic color.

15. The full-color LED display of claim 12, wherein an average decay time measured at 300 K is longer than an average decay time measured at 10 K.

16. The full-color LED display of claim 12, wherein, in emission measured at 300 K, delayed luminescence arising from shallow and deep traps contributes more than band-gap luminescence.

17. The full-color LED display of claim 12, wherein, in emission measured at 300 K, delayed luminescence arising from shallow and deep traps contributes at least twice as much as band-gap luminescence.

18. The full-color LED display of claim 15, wherein the average decay time measured at 300 K is at least 15% longer than the average decay time measured at 10 K.

19. The full-color LED display of claim 12, wherein, in Raman spectral analysis, a ratio of the peak area of a Ga-vacancy-related defect mode located around 687 cm⁻¹ to the peak area of a GaN A₁(LO) mode located around 746.62 cm⁻¹ is 8% or less.

20. The full-color LED display of claim 12, wherein dangling bond formed on the sidewall of each LED device is adsorbed with water molecules.
